(19) United States
(12) Patent Application Publication
(10) Pub. No.: US 2024/0215352 A1
(43) Pub. Date: Jun. 27, 2024

(54) DISPLAY DEVICE

(71) Applicant: Samsung Display Co., Ltd., Yongin-si (KR)

(72) Inventors: JEONGYOON LEE, Yongin-si (KR); KYUNGHO KIM, Yongin-si (KR); OK-KYUNG PARK, Yongin-si (KR)

(21) Appl. No.: 18/389,876

(22) Filed: Dec. 20, 2023

(30) Foreign Application Priority Data
Dec. 21, 2022 (KR) 10-2022-0180971

(51) Int. Cl. H10K 59/131; H10K 59/40

(52) U.S. Cl. CPC H10K 59/131; H10K 59/40

(57) ABSTRACT

Provided is a display device. The display device includes a separator including a first opening region, a first light-emitting device disposed in the first opening and including a first electrode and a second electrode arranged on the first electrode, and a sensing electrode arranged on the separator to overlap the separator in a plan view, wherein a width of the sensing electrode is equal to or less than a width of the separator.

### CROSS-REFERENCE TO RELATED APPLICATIONS

This U.S. non-provisional patent application claims priority under 35 U.S.C. § 119 to Korean Patent Application No. 10-2022-0180971, filed on Dec. 21, 2022, the entire contents of which are hereby incorporated by reference.

### BACKGROUND

The present disclosure herein relates to a display device, and more particularly, to a display device with improved sensing sensitivity.

In general, electronic devices for providing images to a user, such as smartphones, digital cameras, laptop computers, navigators, and smart televisions, include a display device for displaying images. The display device generates an image and provides the generated image to a user through a display screen.

The display device includes a display layer for generating an image and a sensing layer for sensing an external input. The display layer includes a plurality of pixels for generating an image and the sensing layer includes a plurality of sensing electrodes for sensing an external input.

When noise occurs between the sensing electrodes and the display layer, driving signals provided to the sensing electrodes may be distorted and the distorted driving signals may affect sensing sensitivity of the sensing layer. Accordingly, research is carried out to reduce noise between the sensing electrodes and the display layer.

### SUMMARY

The present disclosure provides a sensing layer having improved sensing sensitivity when providing a display layer with reduced image sticking defect and improved lifespan.

An embodiment of the inventive concept provides a display device including: a separator including a first opening region; a first light-emitting device disposed in the first opening and including a first electrode and a second electrode disposed on the first electrode a sensing; and a sensing electrode disposed on the separator to overlap the separator in a plan view, wherein a width of the sensing electrode is equal to or less than a width of the separator.

In an embodiment, the separator may further include a second opening, the display device may further include a second light emitting device disposed in the second opening and including a first electrode and a second electrode disposed on the first electrode, the sensing electrode may include: a first sensing electrode extending in a first direction; and a second sensing electrode extending in a second direction different from the first direction and insulatively intersecting the first sensing electrode, wherein the first sensing electrode may include a first mesh line extending in the first direction and the second direction and the second sensing electrode may include a second mesh line extending in the first direction and the second direction.

In an embodiment, in a plan view, the first mesh line may have the same shape as a portion of the separator corresponding thereto and the second mesh line may have the same shape a portion of the separator corresponding thereto.

In an embodiment, the display device may further include transistors electrically connected to each of the second electrode of the first light-emitting device and the second electrode of the second light-emitting device.

In an embodiment, the display device may further include: a first connection line including a first driver connection part connected to a transistor electrically connected to the first light-emitting device and a first emission connection part spaced apart from the first driver connection part in a plan view and connected to the second electrode of the first light-emitting device; and a second connection line including a second driver connection part connected to a transistor electrically connected to the second light-emitting device and a second emission connection part spaced apart from the second driver connection part in a plan view and connected to the second electrode of the second light-emitting device.

In an embodiment, the first light-emitting device may include a first emission part configured to emit first-color light, the first emission connection part may be spaced apart from the first emission part in a plan view, and the first emission part and the first emission connection part may be at least partially surrounded by at least one of the first mesh line or the second mesh line.

In an embodiment, the first mesh line and the second mesh line may have a curved shape at a portion adjacent to the first emission connection part and the second emission connection part.

In an embodiment, the first mesh line and the second mesh line may include portions facing each other with one of the first emission connection part and the second emission connection part disposed therebetween.

In an embodiment, the first mesh line and the second mesh line may include portions facing each other between the first emission connection part and the second emission connection part.

In an embodiment, the first sensing electrode may include first sensing patterns arranged in the first direction and first intermediate patterns arranged between the first sensing patterns, the second sensing electrode may include second sensing patterns arranged in the second direction and second intermediate patterns arranged between the second sensing patterns, the first sensing patterns, the first intermediate patterns, and the second sensing patterns may be arranged on the same layer, and the second intermediate pattern may be arranged on a different layer from the layer on which the second sensing patterns are disposed.

In an embodiment, the first sensing patterns and the first intermediate patterns may constitute the first mesh line, and the second sensing patterns may constitute the second mesh line.

In an embodiment, an outer periphery portion of the first mesh line constituting an outer periphery of each of the first sensing patterns may surround a portion of the first emission connection part or a portion of the second emission connection part.

In an embodiment, the display device may further include a first insulating layer, a second insulating layer, and a third insulating layer sequentially laminated on the separator, wherein the first sensing patterns, the first intermediate patterns, and the second sensing patterns may be arranged on the second insulating layer and covered by the third insulating layer, and the second intermediate patterns may be arranged on the first insulating layer and covered by the second insulating layer, and the second sensing patterns and the second intermediate patterns may be connected through a contact hole formed in the second insulating layer.

In an embodiment, the display device may further include a 1-1st connection line, a 1-2nd connection line, and a 2-1st connection line, wherein the first light-emitting device may include a 1-1st light-emitting device and a 1-2nd light-emitting device arranged spaced apart from each other with the second light-emitting device disposed therebetween, the 1-1st connection line may include a 1-1st emission connection part connected to the 1-1st light-emitting device, the 1-2nd connection line may include a 1-2nd emission connection part connected to the 1-2nd light-emitting device, and the 2-1st connection line may include a 2-1st emission connection part connected to the second light-emitting device, and the 1-1st emission connection part and the 1-2nd emission connection part may be spaced apart from each other in the second direction with the 2-1st emission connection part disposed therebetween.

In an embodiment, the 1-1st light-emitting device may include a 1-1st emission part that provides first-color light, the 1-2nd light-emitting device may include a 1-2nd emission part that provides the first-color light, and the second light-emitting device may include a 2-1st emission part that provides second-color light having a different color from the first-color light, the 1-1st emission part and the 1-2nd emission part may be spaced apart in the second direction with the 2-1st emission part disposed therebetween, and the 1-1st emission connection part may be spaced apart from the 1-1st emission part in the second direction, and the 1-2nd emission connection part may be spaced apart from the 1-2nd emission part in an opposite direction to the second direction.

In an embodiment, a portion of the first mesh line may be arranged between the 1-1st emission connection part and the 2-1st emission connection part, and a portion of the second mesh line may be arranged between the 1-2nd emission connection part and the 2-1st emission connection part.

In an embodiment, a portion of the first mesh line and a portion of the second mesh line may be arranged spaced apart from each other between the 1-1st emission connection part and the 2-1st emission connection part.

In an embodiment, the first sensing electrode may include first sensing patterns arranged in the first direction and first intermediate patterns arranged between the first sensing patterns, and the first intermediate patterns may include a first intermediate line extending in the first direction and a second intermediate line extending in the first direction and facing the first intermediate line in the second direction.

In an embodiment, the first intermediate line may intersect a portion between the 1-1st emission connection part and the 2-1st emission connection part, and the second intermediate line may intersect a portion between the 1-2nd emission connection part and the 2-1st emission connection part.

In an embodiment, the second sensing electrode may include second sensing patterns arranged in the second direction and second intermediate patterns arranged between the second sensing patterns, and each of the second intermediate patterns may include a bridge line extending in the second direction and insulatively intersecting the first intermediate line and the second intermediate line.

In an embodiment, the display device may further include: a 3-1st light-emitting device spaced apart from the 1-2nd light-emitting device in the first direction; a fourth light-emitting device spaced apart from the second light-emitting device in the first direction; a 3-2nd light-emitting device spaced apart from the 1-1st light-emitting device in the first direction and spaced apart from the 3-1st light-emitting device in the second direction with the fourth light-emitting device disposed therebetween; a 3-1st connection line including a 3-1st emission connection part connected to the 3-1st light- emitting device; a 2-2nd connection line including a 2-2nd emission connection part connected to the fourth light-emitting device; and a 3-2nd connection line including a 3-2nd emission connection part connected to the 3-2nd light-emitting device, wherein the 3-2nd, 2-2nd, and 3-1st emission connection parts may be spaced apart from the 1-1st, 2-1st, and 1-2nd emission connection parts in the first direction, respectively, and the 3-1st emission connection part may be spaced apart from the 3-2nd emission connection part in the second direction with the 2-2nd emission connection part disposed therebetween.

In an embodiment, the 1-1st and 1-2nd light-emitting devices may respectively include 1-1st and 1-2nd emission parts that provide first-color light, the second and fourth light-emitting devices may respectively include 2-1st and 2-2nd emission parts that provide second-color light having a different color from the first-color light, and the 3-1st and 3-2nd light-emitting devices may respectively include 3-1st and 3-2nd emission parts that provide third-color light having a different color from the first-color light and the second-color light, the 1-1st emission part and the 1-2nd emission part may be spaced apart in the second direction with the 2-1st emission part disposed therebetween, the 3-1st emission part and the 3-2nd emission part may be spaced apart in the second direction with the 2-2nd emission part disposed therebetween, and the 1-1st, 2-1st, and 1-2nd emission parts may be spaced apart from the 3-2, 2-2nd, and 3-1st emission parts respectively in the first direction, and the 1-1st and 3-2nd emission connection parts may be spaced apart from the 1-1st and 3-2 emission parts respectively in the second direction, and the 1-2nd and 3-1st emission connection parts may be spaced apart from the 1-2nd and 3-1st emission parts respectively in an opposite direction to the second direction.

In an embodiment, a portion of the first mesh line may intersect a portion between the 1-1st emission connection part and the 2-1st emission connection part and a portion between the 3-2nd emission connection part and the 2-2nd emission connection part, and a portion of the second mesh line may pass across a portion between the 1-2nd emission connection part and the 2-1st emission connection part or a portion between the 3-1st emission connection part and the 2-2nd emission connection part.

In an embodiment, in a plan view, the first mesh line and the second mesh line each may extend in one direction between the second electrode of the first light-emitting device and the second electrode of the second light-emitting device, and the first mesh line and the second mesh line may face each other in the one direction.

In an embodiment, in a plan view, the first mesh line and the second mesh line may be spaced apart and face each other with the second electrode of the first light-emitting device disposed therebetween.

In an embodiment, in a plan view, the first mesh line and the second mesh line each may extend in one direction between the second electrode of the first light-emitting device and the second electrode of the second light-emitting device, and the first mesh line and the second mesh line may face each other in a direction intersecting the one direction.

In an embodiment, the separator may include a first separator overlapping the first mesh line and a second separator overlapping the second mesh line and spaced apart from the first separator.

In an embodiment, the first separator and the second separator may be disposed between adjacent light-emitting devices.

In an embodiment, the display device may further include a dummy conductive pattern arranged on the separator, including the same material as the second electrode, and electrically connected to a power supply line, wherein at least a portion of an outer surface of the separator may have a smaller internal angle than an inner surface of the separator.

In an embodiment, the at least a portion of the outer surface of the separator may have the internal angle of 95 degrees or less.

In an embodiment, the display device may further include an encapsulation layer covering the first light-emitting device, the second light-emitting device, and the separator, wherein the sensing electrode may be arranged on the encapsulation layer.

In an embodiment of the inventive concept, a display device includes: transistors; light-emitting devices arranged on the transistors; connection lines connecting the transistors and the light-emitting devices respectively; a first sensing electrode extending in a first direction; and a second sensing electrode extending in a second direction and insulatively intersecting the first sensing electrode, wherein the connection lines each include: a driver connection part connected to a corresponding transistor among the transistors; and an emission connection part spaced apart from the driver connection part in a plan view and connected to a corresponding light-emitting device among the light-emitting devices, wherein the first sensing electrode and the second sensing electrode are spaced apart from each other between adjacent emission connection parts among the emission connection parts of the connection lines.

### BRIEF DESCRIPTION OF DRAWINGS

The accompanying drawings are included to provide a further understanding of the inventive concept and are incorporated in and constitute a part of this specification. The drawings illustrate embodiments of the inventive concept and, together with the description, serve to explain principles of the inventive concept. In the drawings:

FIG. 1 is a block diagram of a display device according to an embodiment of the inventive concept;

FIGS. 2A and 2B are equivalent circuit diagrams of a pixel according to an embodiment of the inventive concept;

FIGS. 3A and 3B are plan views illustrating a display panel according to an embodiment of the inventive concept;

FIGS. 4A, 4B and 4C are enlarged plan views illustrating some of components of a display panel in a display area according to an embodiment of the inventive concept;

FIGS. 5A and 5B are enlarged cross-sectional views illustrating a partial region of a display panel, taken along line I-I′ of FIG. 4A, according to an embodiment of the inventive concept;

FIG. 6A is a plan view illustrating a sensing layer according to an embodiment of the inventive concept;

FIG. 6B is a cross-sectional view illustrating some components of a display panel according to an embodiment of the inventive concept;

FIG. 7 is an enlarged plan view illustrating some of components of a display panel in a display area according to an embodiment of the inventive concept;

FIGS. 8A and 8B are enlarged cross-sectional views illustrating a partial region of a display panel, taken along line II-II′ of FIG. 7, according to an embodiment of the inventive concept;

FIG. 9 is an enlarged plan view illustrating some of components of a display panel in a display area according to an embodiment of the inventive concept;

FIG. 10 is an enlarged cross-sectional view illustrating a partial region of a display panel, taken along line III-III′ of FIG. 9, according to an embodiment of the inventive concept;

FIG. 11 is an enlarged plan view illustrating some of components of a display panel in a display area according to an embodiment of the inventive concept;

FIG. 12 is an enlarged cross-sectional view illustrating a partial region of a display panel, taken along line IV-IV′ of FIG. 11, according to an embodiment of the inventive concept;

FIG. 13 is a plan view illustrating some of components of a display panel according to an embodiment of the inventive concept; and

FIGS. 14A and 14B are enlarged cross-sectional views illustrating a partial region of a display panel, taken along line V-V′ of FIG. 13, according to an embodiment of the inventive concept.

### DETAILED DESCRIPTION

It will be understood that when an element (or a region, layer, portion, or the like) is referred to as being “on”, “connected to”, or “coupled to” another element, it can be directly on or directly connected/coupled to the other element, or a third element may be present therebetween.

The same reference numerals refer to the same elements. In the drawings, the thicknesses, ratios, and dimensions of elements are exaggerated for clarity of illustration. As used herein, the term “and/or” includes any combinations that can be defined by associated elements.

The terms “first”, “second” and the like may be used for describing various elements, but the elements should not be construed as being limited by the terms. Such terms are only used for distinguishing one element from other elements. For example, a first element could be termed a second element and vice versa without departing from the scope of the right of the present invention. The terms of a singular form may include plural forms unless otherwise specified.

Furthermore, the terms “under”, “lower side”, “on”, “upper side”, and like are used to describe association relationships among elements illustrated in the drawings. The terms, which are relative concepts, are used on the basis of directions illustrated in the drawings.

It will be further understood that the terms “include”, “including”, “has”, “having”, and the like, when used in this specification, specify the presence of stated features, numbers, steps, operations, elements, components, or combinations thereof, but do not preclude the presence or addition of one or more other features, numbers, steps, operations, elements, components, or combinations thereof.

All of the terms used herein (including technical and scientific terms) have the same meanings as understood by those skilled in the art, unless otherwise defined. Terms in common usage such as those defined in commonly used dictionaries should be interpreted to contextually match the lexical meanings in the relevant art and should not be interpreted in an idealized or overly formal sense unless otherwise defined explicitly.

Hereinafter, embodiments of the inventive concept will be described in detail with reference to the accompanying drawings.

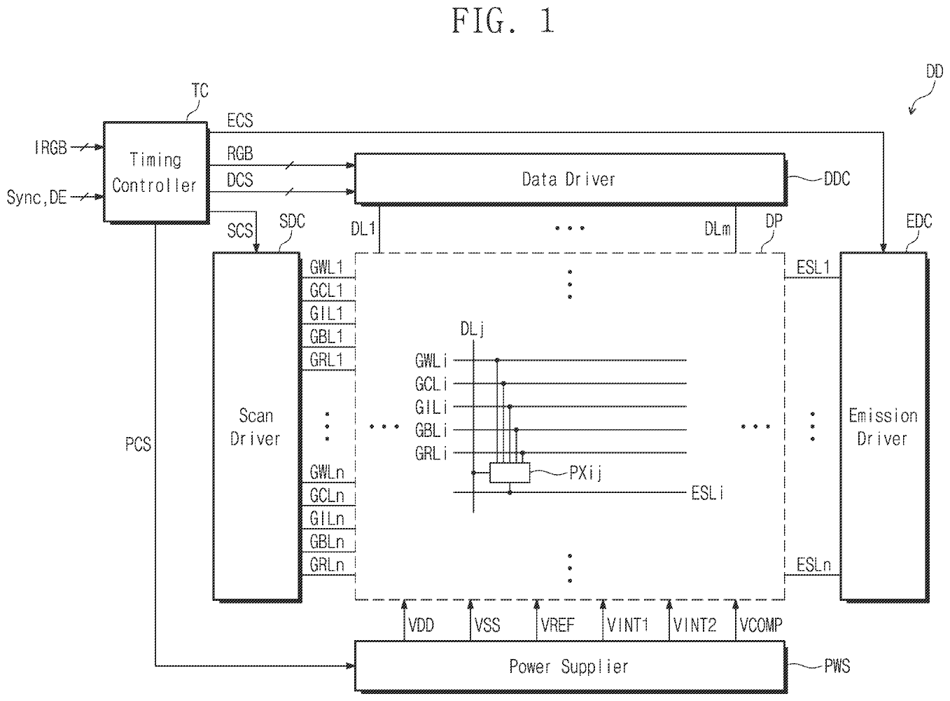

FIG. 1 is a block diagram of a display device according to an embodiment of the inventive concept.

Referring to FIG. 1, a display device DD may include a display panel DP, panel drivers SDC, EDC, and DDC, a power supplier PWS, and a timing controller TC. In the present embodiment, the display panel DP is described as an emissive display panel. The emissive display panel may include an organic light-emitting display panel, an inorganic light-emitting display panel, or a quantum dot light-emitting display panel. In the following embodiments, the organic light-emitting display panel will be described in detail as an example. The panel drivers may include a scan driver SDC, an emission driver EDC, and a data driver DDC.

The display panel DP may include scan lines GWL1 to GWLn, GCL1 to GCLn, GIL1 to GILn, GBL1 to GBLn, and GRL1 to GRLn, emission lines ESL1 to ESLn, and data lines DL1 to DLm. The display panel DP may include a plurality of pixels connected to the scan lines GWL1 to GWLn, GCL1 to GCLn, GIL1 to GILn, GBL1 to GBLn, and GRL1 to GRLn, emission lines ESL1 to ESLn, and data lines DL1 to DLm (where m and n are integers larger than 1).

For example, a pixel PXij (where i and j are integers larger than 1) positioned at an i-th horizontal line (or i-th pixel row) and a j-th vertical line (or j-th pixel column) may be connected to an i-th first scan line (or write scan line GWLi), an i-th second scan line (or compensation scan line GCLi), an i-th third scan line (or first initialization scan line GILi), an i-th fourth scan line (or second initialization scan line GBLi), an i-th fifth scan line (or reset scan line GRLi), a j-th data line DLj, and an i-th emission line ESLi.

The pixel PXij may include a light-emitting device, a plurality of transistors, and at least one capacitor. The pixel PXij may be supplied with a first power supply voltage (or first driving voltage) VDD, a second power supply voltage (or second driving voltage) VSS, a third power supply voltage (or reference voltage) VREF, a fourth power supply voltage (or first initialization voltage) VINT1, a fifth power supply voltage (or second initialization voltage) VINT2, and a sixth power supply voltage (or compensation voltage) VCOMP through the power supplier PWS.

Voltage values of the first power supply voltage VDD and the second power supply voltage VSS are set to cause a light-emitting device to emit light by allowing current to flow therethrough. For example, the first power supply voltage VDD may be set higher than the second power supply voltage VSS.

The third power supply voltage VREF may be a voltage for initializing a gate of a driving transistor T1 included in the pixel PXij. The third power supply voltage VREF may be used to achieve a predetermined gradation using a voltage difference between a data signal and the third power supply voltage VREF. To this end, the third power supply voltage VREF may be set to a predetermined voltage within a voltage range of a data signal.

The fourth power supply voltage VINT1 may be a voltage for initializing a capacitor included in the pixel PXij. The fourth power supply voltage VINT1 may be set lower than the third power supply voltage VREF. For example, the fourth power supply voltage VINT1 may be set to a voltage lower than a difference between the third power supply voltage VREF and a threshold voltage of a driving transistor. However, an embodiment of the inventive concept is not limited thereto.

The fifth power supply voltage VINT2 may be a voltage for initializing a cathode of a light-emitting device included in the pixel PXij. The fifth power supply voltage VINT2 may be set to a voltage lower than the first power supply voltage VDD or the fourth power supply voltage VINT1 or a voltage that is similar or equal to the third power supply voltage VREF but is not limited thereto and may be set to a voltage that is similar or equal to the first power supply voltage VDD.

The sixth power supply voltage VCOMP may supply a predetermined current to a driving transistor when compensating a threshold voltage of the driving transistor.

Meanwhile, although FIG. 1 illustrates that all the first to sixth power supply voltages VDD, VSS, VREF, VINT1, VINT2, and VCOMP are supplied from the power supplier PWS, an embodiment of the inventive concept is not limited thereto. For example, the first power supply voltage VDD and the second power supply voltage VSS both may be supplied regardless of a structure of the pixel PXij, and at least one of the third power supply voltage VREF, the fourth power supply voltage VINT1, the fifth power supply voltage VINT2, or the sixth power supply voltage VCOMP may not be supplied according to the structure of the pixel PXij.

In an embodiment of the inventive concept, signal lines connected to the pixel PXij may be variously configured according to a circuit structure of the pixel PXij.

The scan driver SDC may receive a first control signal SCS from the timing controller TC and may supply a scan signal to each of the first scan lines GWL1 to GWLn, second scan lines GCL1 to GCLn, third scan lines GIL1 to GILn, fourth scan lines GBL1 to GBLn, and fifth scan lines GRL1 to GRLn in response to the first control signal SCS.

The scan signal may be set to a voltage at which transistors supplied with the scan signal may be turned on. For example, the scan signal supplied to a P-type transistor may be set to a logic low level, and the scan signal supplied to an N-type transistor may be set to a logic high level. Hereinafter, the wording “scan signal is supplied” May indicate that the scan signal is supplied at a logic level at which a transistor controlled by the scan signal is turned on.

For convenience, FIG. 1 illustrates the scan driver SDC as a single element, but an embodiment of the inventive concept is not limited thereto. According to the embodiment, a plurality of scan drivers may be included to supply the scan signal to each of the first scan lines GWL1 to GWLn, second scan lines GCL1 to GCLn, third scan lines GIL1 to GILn, fourth scan lines GBL1 to GBLn, and fifth scan lines GRL1 to GRLn.

The emission driver EDC may supply an emission signal to the emission lines ESL1 to ESLn in response to a second control signal ECS. For example, the emission signal may be sequentially supplied to the emission lines ESL1 to ESLn.

Transistors connected to the emission lines ESL1 to ESLn of an embodiment of the inventive concept may be configured with N-type transistors. Here, the emission signal supplied to the emission lines ESL1 to ESLn may be set to a gate on voltage. Transistors that receive the emission signal may be turned off when the emission signal is supplied, otherwise may be set to a turn on state.

The second control signal ECS may include an emission start signal and clock signals, and the emission driver EDC may be implemented as a shift register that sequentially generates and outputs pulse-type emission signals by sequentially shifting the pulse-type emission start signal using the clock signals.

The data driver DDC may receive a third control signal DCS and image data RGB from the timing controller TC. The data driver DDC may convert the image data RGB of a digital format into an analog data signal (i.e., data signal). The data driver DDC may supply a data signal to the data lines DL1 to DLm according to the third control signal DCS.

The third control signal DCS may include a data clock signal, a horizontal start signal, and a data enable signal instructing output of a valid data signal. For example, the data driver DDC may include a shift register that generates a sampling signal by shifting the horizontal start signal in synchronization with the data clock signal, a latch that latches the image data RGB in response to the sampling signal, a digital-to-analog converter (or decoder) that converts the latched image data (e.g., digital data) into analog data signals, and buffers (or amplifiers) that output the data signals to the data lines DL1 to DLm.

The power supplier PWS may supply the display panel DP with the first power supply voltage VDD, the second power supply voltage VSS, and the third power supply voltage VREF for driving the pixel PXij. Furthermore, the power supplier PWS may supply the display panel DP with at least one of the fourth power supply voltage VINT1, the fifth power supply voltage VINT2, or the sixth power supply voltage VCOMP.

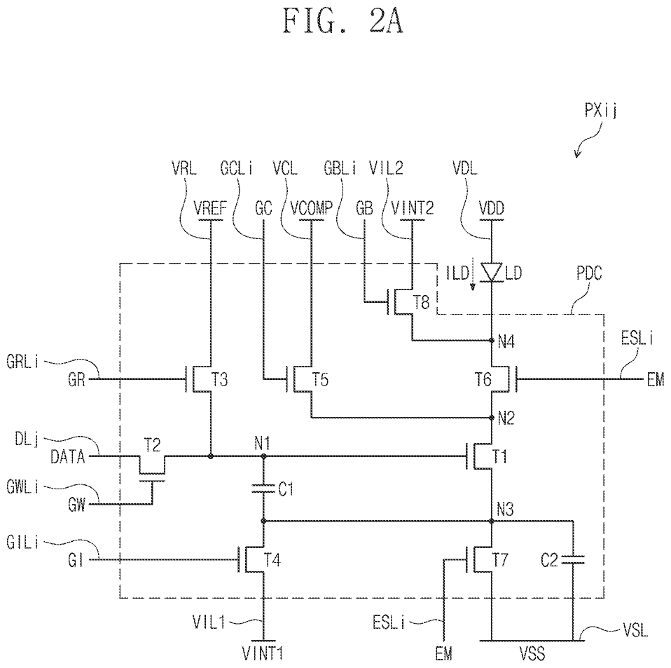

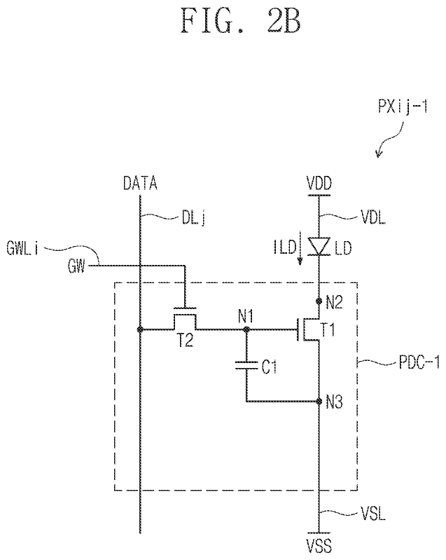

For example, the power supplier PWS may supply each of the first power supply voltage VDD, the second power supply voltage VSS, the third power supply voltage VREF, the fourth power supply voltage VINT1, the fifth power supply voltage VINT2, and the sixth power supply voltage VCOMP to the display panel DP via a first power supply line VDL (see FIG. 2A), a second power supply line VSL (see FIG. 2A), a third power supply line (or reference voltage line) VRL (see FIG. 2A), a fourth power supply line (or first initialization voltage line) VIL1 (see FIG. 2A), a fifth power supply line (or second initialization voltage line) VIL2 (see FIG. 2A), and a sixth power supply line (or compensation voltage line) VCL (see FIG. 2A).

The power supplier PWS may be implemented as a power management integrated circuit but is not limited thereto.

The timing controller TC may generate the first control signal SCS, the second control signal ECS, the third control signal DCS, and a fourth control signal PCS on the basis of input image data IRGB, a synchronization signal Sync (e.g., vertical synchronization signal, horizontal synchronization signal, etc.), a data enable signal DE, and a clock signal. The first control signal SCS may be supplied to the scan driver SDC, the second control signal ECS may be supplied to the emission driver EDC, the third control signal DCS may be supplied to the data driver DDC, and the fourth control signal PCS may be supplied to the power supplier PWS. The timing controller TC may generate the image data RGB (or frame data) by re-sorting the input image data IRGB according to arrangement of the pixels PXij in the display panel DP.

Meanwhile, the scan driver SDC, the emission driver EDC, the data driver DDC, the power supplier PWS, and/or the timing controller TC may be directly formed in the display panel DP or may be provided in a form of a separate driving chip and connected to the display panel DP. Furthermore, at least two of the scan driver SDC, the emission driver EDC, the data driver DDC, the power supplier PWS, and the timing controller TC may be provided as a single driving chip. For example, the data driver DDC and the timing controller TC may be provided as a single driving chip.

The display device DD according to an embodiment has been described with reference to FIG. 1, but the display device of an embodiment of the inventive concept is not limited thereto. Signal lines may be further added or omitted according to a configuration of pixels. Furthermore, a connection relationship between a single pixel and signal lines may be changed. When any one of signal lines is omitted, another signal line may replace the omitted signal line.

FIGS. 2A and 2B are equivalent circuit diagrams of a pixel according to an embodiment of the inventive concept. FIGS. 2A and 2B illustrate examples of equivalent circuit diagrams of the pixels PXij and PXij-1 connected to the i-th first scan line GWLi (hereinafter first scan line) and the j-th data line DLj (hereinafter data line).

As illustrated in FIG. 2A, the pixel PXij includes a light-emitting device LD and a pixel driver PDC. The light-emitting device LD is connected between the first power supply line VDL and the pixel driver PDC.

The pixel driver PDC may be connected to the plurality of scan lines GWLi, GCLi, GILi, GBLi, and GRLi, the data line DLj, the emission line ESLi, and the plurality of power supply lines VDL, VSL, VIL1, VIL2, VRL, and VCL. The pixel driver PDC may include first to eighth transistors T1 to T8, a first capacitor C1, and a second capacitor C2. Hereinafter, the first to eighth transistors T1 to T8 are all assumed to be N-type transistors. However, an embodiment of the inventive concept is not limited thereto, and some of the first to eighth transistors T1 to T8 may be N-type transistors and the others may be P-type transistors, or the first to eighth transistors T1 to T8 each may be P-type transistor.

A gate of the first transistor T1 may be connected to a first node N1. A first electrode of the first transistor T1 may be connected to a second node N2 and a second electrode may be connected to a third node N3. The first transistor T1 may be a driving transistor. The first transistor T1 may control a driving current ILD flowing from the first power supply line VDL to the second power supply line VSL via the light-emitting device LD according to a voltage of the first node N1. Here, the first power supply voltage VDD may be set to a voltage having higher potential than the second power supply voltage VSS.

In the present disclosure, “electrically connecting between a transistor and a signal line or between a transistor and another transistor” represents that “a source, drain, and gate of a transistor have an integrated form with a signal line or are connected thereto via a connection electrode.”

The second transistor T2 may include a gate connected to the write scan line GWLi, a first electrode connected to the date line DLj, and a second electrode connected to the first node N1. The second transistor T2 may supply a data signal DATA to the first node N1 in response to a write scan signal GW transferred through the write scan line GWLi. When the write scan signal GW is supplied to the write scan line GWLi, the second transistor T2 may be turned on to electrically connect the data line DLj and the first node N1.

The third transistor T3 may be connected between the first node N1 and the reference voltage line VRL. A first electrode of the third transistor T3 may receive the reference voltage VREF through the reference voltage line VRL and a second electrode of the third transistor T3 may be connected to the first node N1. In the present embodiment, a gate of the third transistor T3 may receive a reset scan signal GR through the i-th fifth scan line GRLi (hereinafter fifth scan line). When the reset scan signal GR is supplied to the reset scan line GRLi, the third transistor T3 may be turned on to provide the reference voltage VREF to the first node N1.

The fourth transistor T4 may be connected between the third node N3 and the first initialization voltage line VIL1. A first electrode of the fourth transistor T4 may be connected to the third node N3, and a second electrode of the fourth transistor T4 may be connected to the first initialization voltage line VIL1 that provides the first initialization voltage VINT1. The fourth transistor T4 may be referred to as a first initialization transistor. A gate of the fourth transistor T4 may receive a first initialization scan signal GI through the i-th third scan line GILi (hereinafter third scan line). When the first initialization scan signal GI is supplied to the first initialization scan line GILi, the fourth transistor T4 may be turned on to supply the first initialization voltage VINT1 to the third node N3.

The fifth transistor T5 may be connected between the compensation voltage line VCL and the second node N2. A first electrode of the fifth transistor T5 may receive the compensation voltage VCOMP through the compensation voltage line VCL and a second electrode of the fifth transistor T5 may be electrically connected to the second node N2 which is connected to the first electrode of the first transistor T1. A gate of the fifth transistor T5 may receive a compensation scan signal GC through the i-th second scan line GCLi (hereinafter second scan line). When the compensation scan signal GC is supplied to the compensation scan line GCLi, the fifth transistor T5 may be turned on to provide the compensation voltage VCOMP to the second node N2, and thus a threshold voltage of the first transistor T1 may be compensated during a compensation period.

The sixth transistor T6 may be connected between the first transistor T1 and the light-emitting device LD. In detail, a gate of the sixth transistor T6 may receive an emission signal EM through the i-th emission line ESLi (hereinafter emission line). A first electrode of the sixth transistor T6 may be connected to a fourth node N4 which is connected to a cathode of the light-emitting device LD, and a second electrode of the sixth transistor T6 may be connected to the second node N2 which is connected to the first electrode of the first transistor T1. The sixth transistor T6 may be referred to as a first emission control transistor. When the emission signal EM is supplied to the sixth transistor T6, the sixth transistor T6 may be turned on to electrically connect the light-emitting device LD and the first transistor T1.

The seventh transistor T7 may be connected between the second power supply line VSL and the third node N3. A first electrode of the seventh transistor T7 may be connected to the third node N3 which is connected to the second electrode of the first transistor T1, and a second electrode of the seventh transistor T7 may receive the second power supply voltage VSS through the second power supply line VSL. A gate of the seventh transistor T7 may be electrically connected to the emission line ESLi. The seventh transistor T7 may be referred to as a second emission control transistor. When the emission signal EM is supplied to the emission line ESLi, the seventh transistor T7 may be turned on to electrically connect the second electrode of the first transistor T1 and the second power supply line VSL.

In the present embodiment, the sixth transistor T6 and the seventh transistor T7 are illustrated as being turned on through the same emission signal EM by being connected to the same emission line ESLi, but this is merely an example, and the sixth transistor T6 and the seventh transistor T7 may be independently turned on in response to different signals. Furthermore, in the pixel driver PDC according to an embodiment of the inventive concept, either the sixth transistor T6 or the seventh transistor T7 may be omitted.

The eighth transistor T8 may be connected between the second initialization voltage line VIL2 and the fourth node N4. That is, the eighth transistor T8 may include a gate connected to the i-th fourth scan line GBLi (hereinafter fourth scan line), a first electrode connected to the second initialization voltage line VIL2, and a second electrode connected to the fourth node N4. The eighth transistor T8 may be referred to as a second initialization transistor. The eight transistor T8 may supply the second initialization voltage VINT2 to the fourth node N4 corresponding to the cathode of the light-emitting device LD in response to the second initialization scan signal GB transferred through the second initialization scan line GBLi. The cathode of the light-emitting device LD may be initialized by the second initialization voltage VINT2.

Meanwhile, in the present embodiment, some of the second to eighth transistor T2 to T8 may be simultaneously turned on in response to the same scan signal. For example, the compensation scan signal GC and the second initialization scan signal GB may be a same scan signal. The eighth transistor T8 and the fifth transistor T5 may be simultaneously turned on in response to the same scan signal. For example, the eighth transistor T8 and the fifth transistor T5 may be operated by the same scan signal. The eighth transistor T8 and the fifth transistor T5 may be simultaneously turned on/off by the same scan signal. In this case, the compensation scan line GCLi and the second initialization scan line GBLi may be provided as a substantially single scan line. Accordingly, initialization of the cathode of the light-emitting device LD and compensation of the threshold voltage of the first transistor T1 may be performed at the same timing. However, this is merely an example, and the above-mentioned configuration is not limited to a certain embodiment.

Furthermore, according to an embodiment of the inventive concept, initialization of the cathode of the light-emitting device LD and compensation of the threshold voltage of the first transistor T1 may be performed by applying the same power supply voltage. For example, the compensation voltage line VCL and the second initialization voltage line VIL2 may be provided as a substantially single power supply voltage line. In this case, since an initialization operation of a cathode and a compensation operation of a driving transistor may be performed using one power supply voltage, a driving unit may be simply designed. However, this is merely an example, and the above-mentioned configuration is not limited to a certain embodiment.

A first capacitor C1 may be connected between the first node N1 and the third node N3. The first capacitor C1 may store a voltage difference between the first node N1 and the third node N3. The first capacitor C1 may be referred to as a storage capacitor.

A second capacitor C2 may be connected between the third node N3 and the second power supply line VSL. That is, one electrode of the second capacitor C2 may be connected to the second power supply line VSL supplied with the second power supply voltage VSS, and the other electrode of the second capacitor C2 may be connected to the third node N3. The second capacitor C2 may store charge corresponding to a voltage difference between the second power supply voltage VSS and the third node N3. The second capacitor C2 may be referred to as a hold capacitor. The second capacitor C2 may have higher capacitance than the first capacitor C1. Accordingly, the second capacitor C2 may minimize a voltage change of the third node N3 in response to a voltage change of the first node N1.

In the present embodiment, the light-emitting device LD may be connected to the pixel driver PDC through the fourth node N4. The light-emitting device LD may include an anode connected to the first power supply line VDL and the cathode opposing the anode. In the present embodiment, the light-emitting device LD may be connected to the pixel driver PDC through the cathode. That is, in the pixel PXij according to an embodiment of the inventive concept, a connection node at which the light-emitting device LD and the pixel driver PDC are connected may be the fourth node N4, and the fourth node N4 may correspond to a connection node between the first electrode of the sixth transistor T6 and the cathode of the light-emitting device LD. Accordingly, potential of the fourth node N4 may substantially correspond to cathode potential of the light-emitting device LD.

In detail, the anode of the light-emitting device LD may be connected to the first power supply line VDL so that the first power supply voltage VDD that is a constant voltage is applied, and the cathode may be connected to the first transistor T1 through the sixth transistor T6. That is, in the present embodiment in which the first to eighth transistors T1 to T8 are N-type transistors, potential of the third node N3 corresponding to the source of the first transistor T1 that is a driving transistor may not be directly affected by characteristics of the light-emitting device LD. Therefore, even if prolonged use of the display panel DP deteriorates the light-emitting device LD, influence of the deterioration of the light-emitting device LD on a gate-source voltage Vgs of transistors constituting the pixel driver PDC, particularly a driving transistor, may reduce. That is, since a variation in a driving current due to the deterioration of the light-emitting device LD may reduce, an image sticking defect of a display panel due to an increase in use time may reduce, and a lifespan of the display panel may be improved.

Alternatively, as illustrated in FIG. 2B, the pixel PXij-1 May include a pixel driver PDC-1 including two transistors T1 and T2 and one capacitor C1. The pixel driver PDC-1 May be connected to the light-emitting device LD, the write scan line GWLi, the data line DLj, and the second power supply line VSL. The pixel driver PDC-1 illustrated in FIG. 2B may correspond to the pixel driver PDC illustrated in FIG. 2A except for the third to eighth transistors T3 to T8 and the second capacitor C2.

The first and second transistors T1 and T2 each may be N-type or P-type transistors. In the present embodiment, the first and second transistors T1 and T2 are assumed to be N-type transistors.

The first transistor T1 may include a gate connected to a first node N1, a first electrode connected to a second node N2, and a second electrode connected to a third node N3. The second node N2 may be a node connected to the first power supply line VDL via the light-emitting device LD, and the third node N3 may be a node connected to the second power supply line VSL. The first transistor T1 may be connected to the light-emitting device LD through the second node N2 and to the second power supply line VSL through the third node N3. The first transistor T1 may be a driving transistor.

The second transistor T2 may include a gate that receives the write scan signal GW through the write scan line GWLi, a first electrode connected to the data line DLj, and a second electrode connected to the first node N1. The second transistor T2 may supply a data signal DATA to the first node N1 in response to the write scan signal GW transferred through the write scan line GWLi.

The capacitor C1 may include one electrode connected to the first node N1 and the other electrode connected to the third node N3. The capacitor C1 may store the data signal DATA transferred to the first node N1.

The light-emitting device LD may include an anode and a cathode. In the present embodiment, the anode of the light-emitting device LD is connected to the first power supply line VDL and the cathode is connected to the pixel driver PDC-1 through the second node N2. In the present embodiment, the cathode of the light-emitting device LD may be connected to the first transistor T1. The light-emitting device LD may emit light according to an amount of current flowing through the first transistor T1.

In the present embodiment in which the first and second transistors T1 and T2 are N-type transistors, the second node N2 at which the cathode of the light-emitting device LD and the pixel driver PDC-1 are connected may correspond to the drain of the first transistor T1. That is, the gate-source voltage Vgs of the first transistor T1 may be prevented from being changed due to the light-emitting device LD. Accordingly, since a variation in a driving current due to the deterioration of the light-emitting device LD may reduce, an image sticking defect of a display panel due to an increase in use time may reduce, and a lifespan of the display panel may be improved.

Meanwhile, FIGS. 2A and 2B illustrate circuits of the pixel drivers PDC and PDC-1 according to an embodiment of the inventive concept, and the number and arrangement of transistors and the number and arrangement of capacitors may be variously designed in the circuits and are not limited to a certain embodiment, provided that the circuits are connected to the cathode of the light-emitting device LD in the display panel according to an embodiment of the inventive concept.

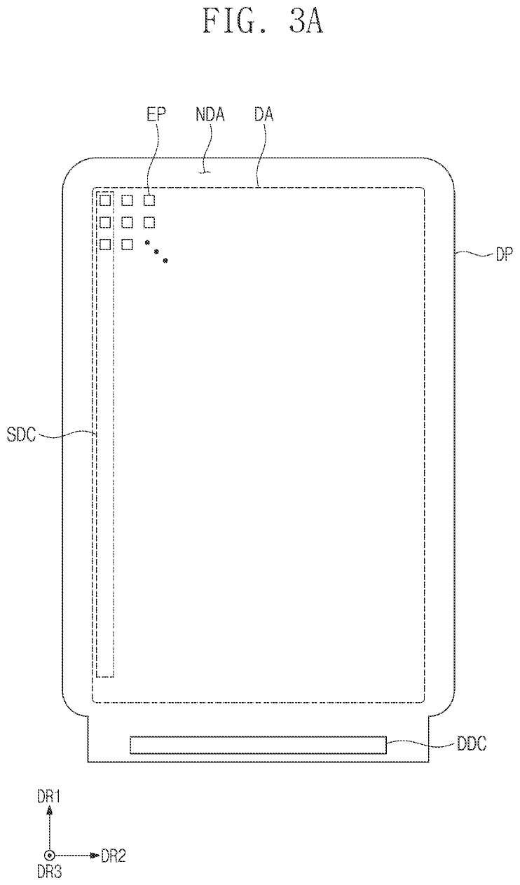

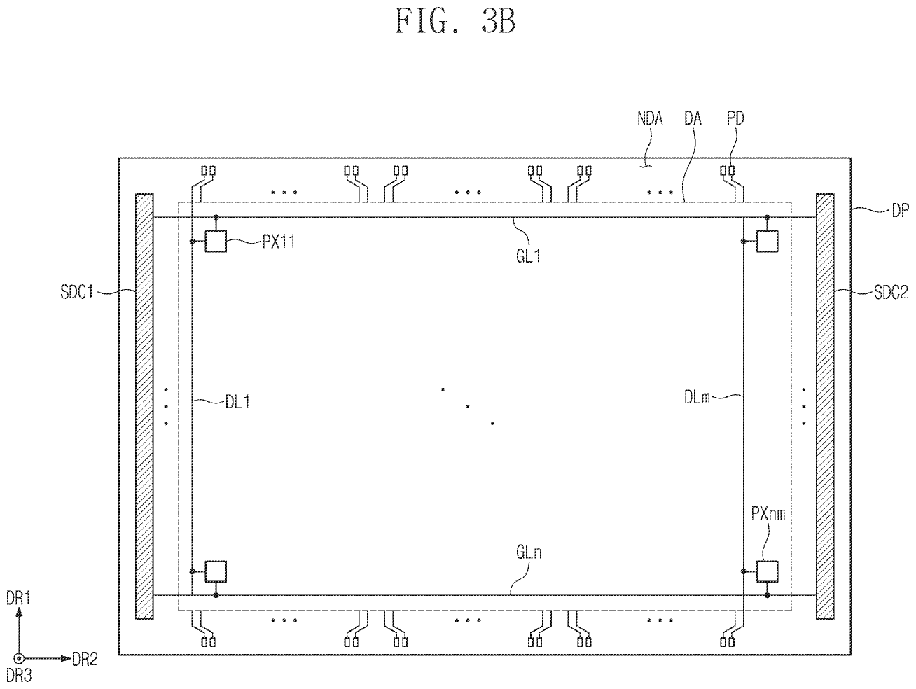

FIGS. 3A and 3B are plan views illustrating a display panel according to an embodiment of the inventive concept. For convenience, some elements are not illustrated and some elements mounted on the display panel DP are illustrated together in FIGS. 3A and 3B.

Referring to FIG. 3A, the display panel DP of an embodiment may include a display area DA and a peripheral area (or non-display area) NDA. The display area DA may include a plurality of emission parts EP.

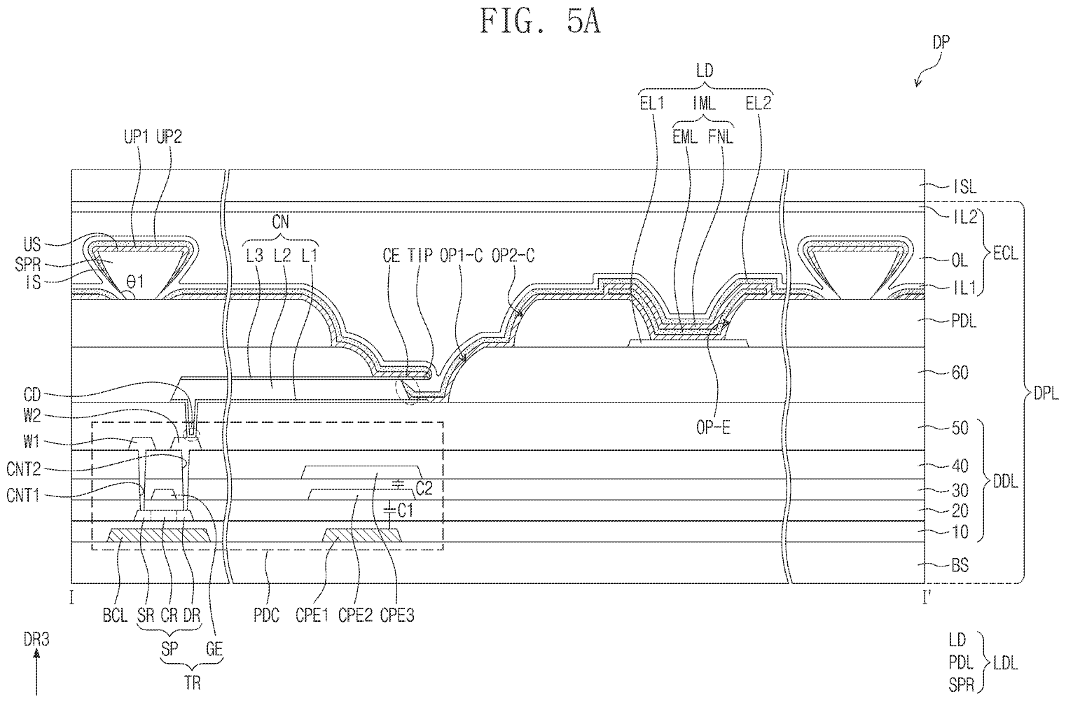

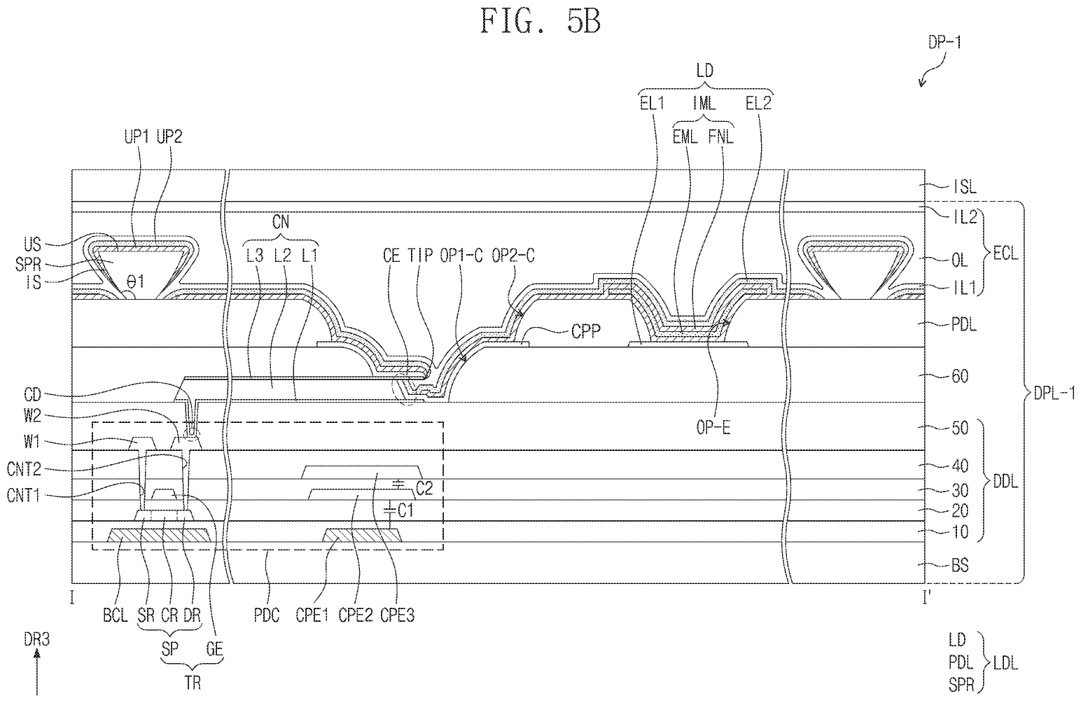

The emission parts EP may be regions in which light is emitted by the pixels PXij (see FIG. 1). In detail, the emission parts EP each may correspond to the emission opening OP-E (see FIG. 5A) that will be described later.

The peripheral area NDA may be arranged adjacent to the display area DA. In the present embodiment, the peripheral area NDA is illustrated in a shape surrounding an edge of the display area DA. However, this is merely an example, and the peripheral area NDA may be arranged on one side of the display area DA or may be omitted, and the configuration of the peripheral area NDA is not limited to a certain embodiment.

In the present embodiment, the scan driver SDC and the data driver DDC may be mounted on the display panel DP. In an embodiment, the scan driver SDC may be arranged in the display area DA and the data driver DDC may be arranged in the peripheral area NDA. The scan driver SDC may overlap, in a plan view, the display area DA. In an embodiment, the scan driver SDC may overlap some of the plurality of emission parts EP. Since the scan driver SDC is arranged in the display area DA, a size of the peripheral area NDA may reduce compared to a typical display panel in which the scan driver is arranged in the peripheral area, and a display device having a narrow bezel may be easily implemented.

Meanwhile, unlike the illustration of FIG. 3A, the scan driver SDC may be provided as two separate parts. The two separate parts of the scan drivers SDC may be spaced apart laterally with a center of the display area DA disposed therebetween. Alternatively, more than two scan drivers SDC may be provided, and the scan driver SDC is not limited to a certain embodiment.

Meanwhile, FIG. 3A illustrates an example of the display panel, and the data driver DDC may be arranged in the display area DA. Here, the data driver DDC may be arranged in the display area DA in a plan view.

In an embodiment, the data driver DDC may be provided in a form of a driving chip independent of the display panel DP and may be connected to the display panel DP. However, this is merely an example, and the data driver DDC may be formed in the same process as the scan driver SDC to form the display panel DP and a configuration of the data driver DDC is not limited to a certain embodiment.

As illustrated in FIG. 3B, a length of the display panel DP in a second direction DR2 may be larger than a length of the display panel DP in a first direction DR1. In the present embodiment, the display panel DP may include a plurality of scan drivers SDC1 and SDC2. The scan drivers SDC1 and SDC2 include, for example, a first scan driver SDC1 and a second scan driver SDC2 that are spaced apart in the second direction DR2. FIG. 3B illustrates a pixel PX11 connected to the data line DL1 and the scan line GL1, . . . , and a pixel PXnm connected to the data line DLm and the scan line GLn.

The first scan driver SDC1 may be connected to a portion of the scan lines GL1 to GLn, and the second scan driver SDC2 may be connected to another portion of the scan lines GL1 to GLn. For example, the first scan driver SDC1 may be connected to odd-numbered scan lines among the scan lines GL1 to GLn, and the second scan driver SDC2 may be connected to even-numbered scan lines among the scan lines GL1 to GLn.

For ease of description, pads PD of the data lines DL1 to DLm are illustrated in FIG. 3B. The pads PD may be disposed at ends of the data lines DL1 to DLm. The data lines DL1 to DLm may be connected to the data driver DDC (see FIG. 3A) through the pads PD.

According to an embodiment of the inventive concept, the pads PD may be arranged to be spaced apart from each other with the display area DA disposed therebetween in the peripheral area NDA. For example, a portion of the pads PD may be arranged on an upper side, i.e., a side adjacent to the first scan line GL1 among the scan lines GL1 to GLn, and another portion of the pads PD may be arranged on a lower side, i.e., a side adjacent to the last scan line GLn among the scan lines GL1 to GLn. In the present embodiment, the pads PD connected to odd-numbered data lines among the data lines DL1 to DLm may be arranged on an upper side, and the pads PD connected to even-numbered data lines among the data lines DL1 to DLm may be arranged on a lower side.

Although not illustrated, the display panel DP may include a plurality of upper data drivers connected to the pads PD arranged on an upper side and/or a plurality of lower data drivers connected to the pads PD arranged on a lower side. However, this is merely an example, and the display panel DP may include one upper data driver connected to the pads PD arranged on an upper side and/or one lower data driver connected to the pads PD arranged on a lower side. That is, the pads PD according to an embodiment of the inventive concept may be arranged only on one side of the display panel DP and connected to a single data driver, and a configuration of the pads PD is not limited to a certain embodiment.

Alternatively, as described above with reference to FIG. 3A, the scan driver and/or the data driver may be arranged in the display area DA in the display panel DP of FIG. 3B. In an embodiment, some of the emission parts may overlap the scan driver and/or the data driver.

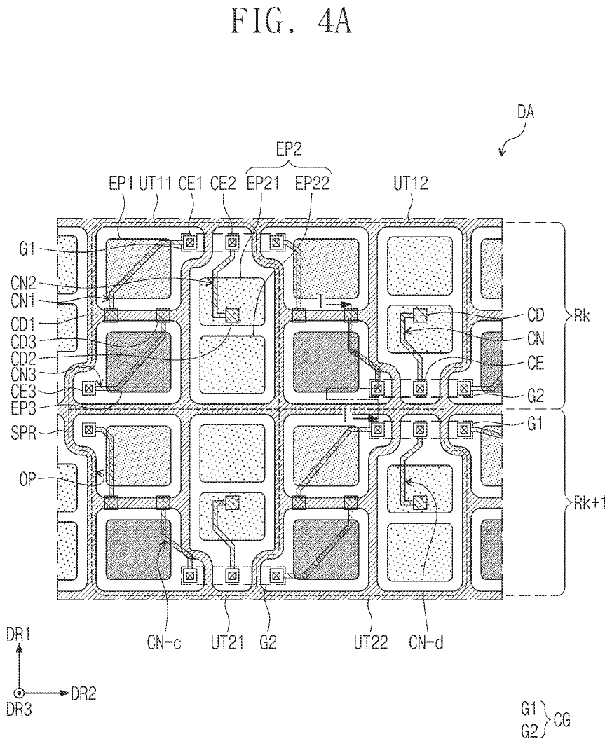

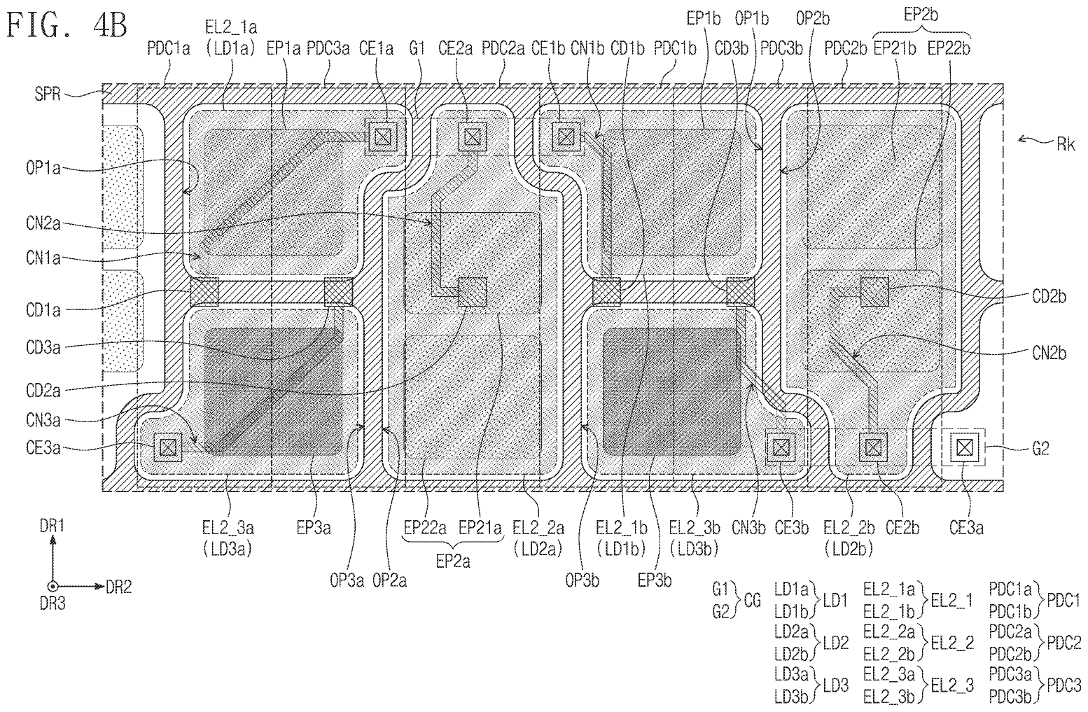

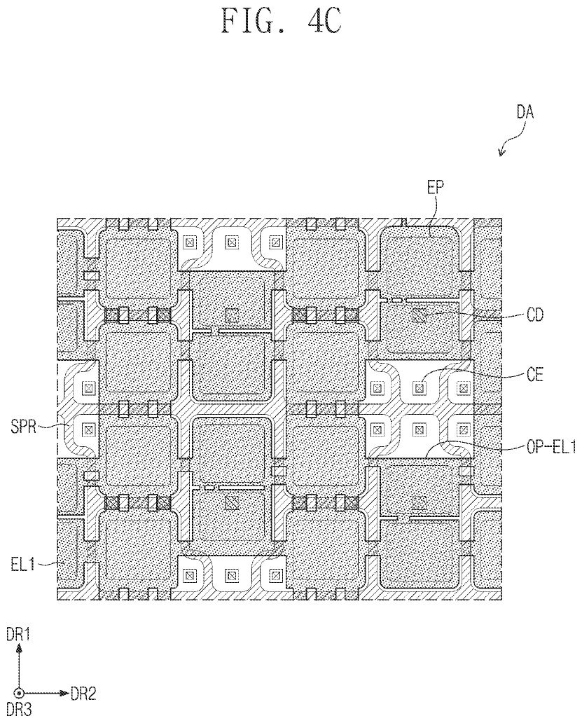

FIGS. 4A to 4C are enlarged plan views illustrating some of elements of a display panel in a display area according to an embodiment of the inventive concept. FIG. 4A illustrates a region in which four light-emitting units UT11, UT12, UT21, and UT22 are arranged in 2 by 2 array, and FIG. 4B illustrates an enlarged view of a portion of the region illustrated in FIG. 4A. Some of the elements illustrated in FIG. 4A are omitted or emphasized in FIG. 4C. Hereinafter, the light-emitting units UT11, UT12, UT21, and UT22 will be described in detail with reference to FIGS. 4A to 4C.

Emission parts of a first row Rk include the emission parts EP1, EP2, and EP3 constituting a first-row first-column light-emitting unit UT11 and a first-row second-column light-emitting unit UT12, and emission parts of a second row Rk+1 include the emission parts EP1, EP2, and EP3 constituting a second-row first-column light-emitting unit UT21 and a second-row second-column light-emitting unit UT22. FIGS. 4A to 4C illustrate a separator SPR, the plurality of emission parts EP1, EP2, and EP3 arranged in regions divided by the separator SPR, connection lines CN1, CN2, and CN3, an anode (or first electrode) EL1, and cathodes (or second electrodes) EL2_1, EL2_2, and EL2_3 among elements of the display panel DP (see FIG. 1).

The emission parts EP1, EP2, and EP3 each may be regions through which light emitted by the light-emitting device LD (see FIG. 2A or 2B) is displayed, and may correspond to a unit constituting an image displayed on the display panel DP (see FIG. 1).

The emission parts EP1, EP2, and EP3 may include a first emission part EP1, a second emission part EP2, and a third emission part EP3. The first emission part EP1, the second emission part EP2, and the third emission part EP3 may emit beams of light of different colors. For example, the first emission part EP1 may display red light, the second emission part EP2 may display blue light, and the third emission part EP3 may display green light, but a combination of colors is not limited thereto. Furthermore, at least two of the emission parts EP1, EP2, and EP3 may emit light of the same color. For example, all of the emission parts EP1, EP2, and EP3 may emit blue light or white light.

Meanwhile, the second emission part EP2 among the emission parts EP1, EP2, and EP3 may include two sub-emission parts EP21 and EP22 spaced apart from each other in the first direction DR1. However, this is merely an example, the second emission part EP2 may be provided as one pattern having an integrated shape like the other emission parts EP1 and EP3, or at least one of the other emission parts EP1 and EP3 may include sub-emission parts, and a configuration of the emission parts is not limited to a certain embodiment.

In the present embodiment, the emission parts of the first row Rk may be configured in a form in which the first-row first-column light-emitting unit UT11 and the first-row second-column light-emitting unit UT12 are repeatedly arranged along the second direction DR2, and the emission parts of the second row Rk+1 May be configured in a form in which the second-row first-column light-emitting unit UT21 and the second-row second-column light-emitting unit UT22 are repeatedly arranged along the second direction DR2. The emission parts of the second row Rk+1 May be substantially configured with the emission parts EP1, EP2, and EP3 shifted from the emission parts of the first row Rk in the second direction DR2. That is, the first-row first-column light-emitting unit UT11 and the second-row second-column light-emitting unit UT22 may be configured with emission parts of the same shape (hereinafter referred to as 1-1st, 2-1st, and 3-1st emission parts EP1a, EP2a, and EP3a), and the first-row second-column light-emitting unit UT12 and the second-row and first-column light-emitting unit UT21 may be configured with emission parts of the same shape (hereinafter referred to as 1-2nd, 2-2nd, and 3-2nd emission parts EP1b, EP2b, and EP3b).

FIG. 4B illustrates enlarged views of two light-emitting units arranged in the first row Rk. In each light-emitting unit, the first emission parts EP1a and EP1b and the third emission parts EP3a and EP3b spaced apart in the first direction DR1 are included, and the second emission parts EP2a and EP2b spaced apart from the first and third emission parts EP1a, EP1b, EP3a, and EP3b in the second direction DR2 may be arranged. The 2-1st emission part EP2a of each of the first-row first-column and second-row second-column light-emitting units UT11 and UT22 may be arranged so as to oppose the 3-1st emission part EP3a to a greater degree than the 1-1st emission part EP1a, and the 2-2nd emission part EP2b of each of the first-row second-column and second-row first-column light-emitting units UT12 and UT21 may be arranged so as to oppose the 1-2nd emission part EP1b to a greater degree than the 3-2nd emission part EP3b. That is, the second emission part EP2a opposing the third emission part EP3a to a greater degree and the second emission part EP2b opposing the first emission part EP1b to a greater degree may be repeatedly arranged in the same row and same column. FIG. 4B exemplarily illustrates that the 2-1st light emission part EP2a of the first-row first-column light-emitting unit UT11 includes two sub-emission parts EP21a and EP22a and the 2-2nd light emission part EP2b of the first-row second-column light-emitting unit UT12 includes two sub-emission parts EP21b and EP22b.

For ease of description, FIG. 4B illustrates a plurality of cathodes EL2_1a, EL2_2a, EL2_3a, EL2_1b, EL2_2b, and EL2_3b, a plurality of pixel drivers PDC1a, PDC2a, PDC3a, PDC1b, PDC2b, and PDC3b, and a plurality of connection lines CN1a, CN2a, CN3a, CN1b, CN2b, and CN3b, which are included in two light-emitting units arranged in the first row Rk.

The cathodes EL2_1a, EL2_2a, EL2_3a, EL2_1b, EL2_2b, and EL2_3b may be electrically disconnected by being separated from each other due to the separator SPR. A plurality of opening regions OP are defined in the separator SPR, and the cathodes EL2_1a, EL2_2a, EL2_3a, EL2_1b, EL2_2b, and EL2_3b may be separately arranged in the opening regions OP. Accordingly, an arrangement and shape of the cathodes EL2_1a, EL2_2a, EL2_3a, EL2_1b, EL2_2b, and EL2_3b may correspond to an arrangement and shape of the opening regions OP of the separator SPR.

1-1st to 3-1st opening regions OP1a, OP2a, and OP3a and 1-2nd to 3-2nd opening regions OP1b, OP2b, and OP3b may be defined in the separator SPR.

Since the 1-1st to 3-1st cathodes EL2_1a, EL2_2a, and EL2_3a are separately arranged in the 1-1st to 3-1st opening regions OP1a, OP2a, and OP3a, it can be said that 1-1st to 3-1st light-emitting devices LD1a, LD2a, and LD3a respectively including the 1-1st to 3-1st cathodes EL2_1a, EL2_2a, and EL2_3a are arranged in correspondence with the 1-1st to 3-1st opening regions OP1a, OP2a, and OP3a. The 1-1st to 3-1st light-emitting devices LD1a, LD2a, and LD3a may provide the 1-1st to 3-1st emission parts EP1a, EP2a, and EP3a, respectively.

Since the 1-2nd to 3-2nd cathodes EL2_1b, EL2_2b, and EL2_3b are separately arranged in the 1-2nd to 3-2nd opening regions OP1b, OP2b, and OP3b, it can be said that 1-2nd to 3-2nd light-emitting devices LD1b, LD2b, and LD3b respectively including the 1-2nd to 3-2nd cathodes EL2_1b, EL2_2b, and EL2_3b are arranged in correspondence with the 1-2nd to 3-2nd opening regions OP1b, OP2b, and OP3b. The 1-2nd to 3-2nd light-emitting devices LD1b, LD2b, and LD3b may provide the 1-2nd to 3-2nd emission parts EP1b, EP2b, and EP3b, respectively. In the present disclosure, the 2-1st light-emitting device LD2a and the 2-2nd light-emitting device LD2b may be referred to as a second light-emitting device and a fourth light-emitting device, respectively.

One light-emitting unit may include the 1-1st to 3-1st light-emitting devices LD1a, LD2a, and LD3a respectively including the 1-1st to 3-1st cathodes EL2_1a, EL2_2a, and EL2_3a, the 1-1st to 3-1st pixel drivers PDC1a, PDC2a, and PDC3a, and 1-1st to 3-1st connection lines CN1a, CN2a, and CN3a. Another adjacent light-emitting unit may include the 1-2nd to 3-2nd light-emitting devices LD1b, LD2b, and LD3b respectively including the 1-2nd to 3-2nd cathodes EL2_1b, EL2_2b, and EL2_3b, the 1-2nd to 3-2nd pixel drivers PDC1b, PDC2b, and PDC3b, and 1-2nd to 3-2nd connection lines CN1b, CN2b, and CN3b. However, this is merely an example, and the number and arrangement of the light-emitting units may be variously designed and are not limited to a certain embodiment.

The 1-1st to 3-1st pixel drivers PDC1a, PDC2a, and PDC3a are respectively connected to the 1-1st to 3-1st light-emitting devices LD1a, LD2a, and LD3a constituting the 1-1st to 3-1st emission parts EP1a, EP2a, and EP3a. The 1-2nd to 3-2nd pixel drivers PDC1b, PDC2b, and PDC3b are respectively connected to the 1-2nd to 3-2nd light-emitting devices LD1b, LD2b, and LD3b constituting the 1-2nd to 3-2nd emission parts EP1b, EP2b, and EP3b. In the present disclosure, the term “connected” indicates not only direct physical connection but also electrical connection.

In the present embodiment, the 1-1st to 3-2nd pixel drivers PDC1a, PDC2a, PDC3a, PDC1b, PDC2b, and PDC3b each may include the transistors described above with reference to FIG. 2A or 2B. The cathodes EL2_1a, EL2_2a, EL2_3a, EL2_1b, EL2_2b, and EL2_3b of the 1-1st to 3-2nd light-emitting devices LD1a, LD2a, LD3a, LD1b, LD2b, and LD3b each may be connected to a corresponding transistor among transistors included in the 1-1st to 3-2nd pixel drivers PDC1a, PDC2a, PDC3a, PDC1b, PDC2b, and PDC3b.

Each of regions in which the pixel drivers PDC1a, PDC2a, PDC3a, PDC1b, PDC2b, and PDC3b illustrated in FIG. 4B are defined in a plan view may correspond to a unit in which transistor and capacitor elements constituting the pixel driver PDC (see FIG. 2A) or PDC-1 (see FIG. 2B) for driving the light-emitting device LD (see FIG. 2A or 2B) of a pixel are repeatedly arranged. In the present embodiment, the 1-1st, 3-1st, and 2-1st pixel drivers PDC1a, PDC3a, and PDC2a may be sequentially arranged in the second direction DR2, and the 1-2nd, 3-2nd, and 2-2nd pixel drivers PDC1b, PDC3b, and PDC2b may also be sequentially arranged in the second direction DR2. Positions or shapes of the pixel drivers PDC1a, PDC2a, PDC3a, PDC1b, PDC2b, and PDC3b may be designed independent of positions or shapes of the emission parts EP1a, EP2a, EP3a, EP1b, EP2b, and EP3b.

For example, the 1-1st to 3-1st pixel drivers PDC1a, PDC2a, and PDC3a may be designed so as to be arranged at positions different from positions of the 1-1st to 3-1st opening regions OP1a, OP2a, and OP3a of the separator SPR, i.e., the 1-1st to 3-1st cathodes EL2_1a, EL2_2a, and EL2_3a, or have shapes different from shapes of the 1-1st to 3-1st cathodes EL2_1a, EL2_2a, and EL2_3a. Alternatively, the 1-1st to 3-1st pixel drivers PDC1a, PDC2a, and PDC3a may be designed so as to be arranged overlapping positions of the 1-1st to 3-1st emission parts EP1a, EP2a, and EP3a and have shapes similar to shapes of the 1-1st to 3-1st opening regions OP1a, OP2a, and OP3a of the separator SPR, for example, the 1-1st to 3-1st cathodes EL2_1a, EL2_2a, and EL2_3a.

In the present embodiment, it is illustrated that the pixel drivers PDC1a, PDC2a, PDC3a, PDC1b, PDC2b, and PDC3b each have a rectangular shape, the emission parts EP1a, EP2a, EP3a, EP1b, EP2b, and EP3b are arranged in a different configuration than the pixel drivers PDC1a, PDC2a, PDC3a, PDC1b, PDC2b, and PDC3b, and the cathodes EL2_1a, EL2_2a, EL2_3a, EL2_1b, EL2_2b, and EL2_3b are arranged at positions overlapping the emission parts EP1a, EP2a, EP3a, EP1b, EP2b, and EP3b, thus forming an irregular shape.

Accordingly, as illustrated in FIG. 4B, the 1-1st pixel driver PDC1a may be arranged at a position partially overlapping the 1-1st emission part EP1a, the 3-1st emission part EP3a, and another adjacent light-emitting unit. The 3-1st pixel driver PDC3a may be arranged at a position overlapping the 1-1st emission part EP1a, the 2-1st emission part EP2a, and the 3-1st emission part EP3a. The 2-1st pixel driver PDC2a may be arranged at a position overlapping the 2-1st emission part EP2a. The 1-2nd to 3-2nd pixel drivers PDC1b, PDC2b, and PDC3b may also be arranged similarly to the 1-1st to 3-1st pixel drivers PDC1a, PDC2a, and PDC3a. However, this is merely an example, and positions of the pixel drivers PDC1a, PDC2a, PDC3a, PDC1b, PDC2b, and PDC3b may be designed in various forms and shapes independent of positions of the emission parts EP1a, EP2a, EP3a, EP1b, EP2b, and EP3b, and are not limited to a certain embodiment.

The connection lines CN may be provided in plurality and spaced apart from each other. The connection lines CN each may connect the pixel driver PDC (see FIG. 2A) or PDC-1 (see FIG. 2B) and the light-emitting device LD (see FIG. 2A or 2B). In detail, the connection lines CN each may correspond to the node (N4 of FIG. 2A or N2 of FIG. 2B) at which the light-emitting device LD (see FIG. 2A or 2B) is connected to the pixel driver PDC (see FIG. 2A) or PDC-1 (see FIG. 2B).

The connection lines CN each may include a first connection part (hereinafter emission connection part) CE and a second connection part (hereinafter driver connection part) CD. The emission connection part CE may be provided on one side of the connection line CN and the driver connection part CD may be provided on the other side of the connection line CN. The emission connection part CE and the driver connection part CD included in one connection line CN may be arranged spaced apart in a plan view.

The driver connection part CD may be a portion of the connection line CN connected to the pixel driver PDC (see FIG. 2A) or PDC-1 (see FIG. 2B). In the present embodiment, the driver connection part CD is connected to one electrode of a transistor constituting the pixel driver PDC (see FIG. 2A) or PDC-1 (see FIG. 2B). In detail, the driver connection part CD may be connected to the drain of the sixth transistor T6 illustrated in FIG. 2A or the drain of the first transistor T1 illustrated in FIG. 2B. Accordingly, a position of the driver connection part CD may correspond to a position of the transistor TR (see FIG. 5A) physically connected to the connection line CN in the pixel driver PDC (see FIG. 2A) or PDC-1 (see FIG. 2B).

The emission connection part CE may be a portion of the connection line CN connected to the light-emitting device LD (see FIG. 2A or 2B). In the present embodiment, the connection line CN may be connected at the emission connection part CE to the cathodes EL2_1a, EL2_2a, EL2_3a, EL2_1b, EL2_2b, and EL2_3b.

One light-emitting unit may include a plurality of the connection lines CN, and the connection lines CN may include a first connection line CN1, a second connection line CN2, and a third connection line CN3. The first connection line CN1 connects the first light-emitting device LD1 forming the first emission part EP1 to the first pixel driver PDC1, the second connection line CN2 connects the second light-emitting device LD2 forming the second emission part EP2 to the second pixel driver PDC2, and the third connection line CN3 connects the third light-emitting device LD3 forming the third emission part EP3 to the third pixel driver PDC3. In detail, the first to third connection lines CN1 to CN3 connect the first to third cathodes EL2_1 to EL2_3 included in the first to third light-emitting devices LD1 to LD3 to the first to third pixel drivers PDC1 to PDC3, respectively.

The first connection line CN1 may include a first driver connection part CD1 connected to the first pixel driver PDC1 and a first emission connection part CE1 connected to the first cathode EL2_1. The second connection line CN2 may include a second driver connection part CD2 connected to the second pixel driver PDC2 and a second emission connection part CE2 connected to the second cathode EL2_2. The third connection line CN3 may include a third driver connection part CD3 connected to the third pixel driver PDC3 and a third emission connection part CE3 connected to the third cathode EL2_3.

In one light-emitting unit, a plurality of the driver connection parts CD may be arranged, and the driver connection parts CD may include a first driver connection part CD1, a second driver connection part CD2, and a third driver connection part CD3.

The first to third driver connection parts CD1 to CD3 may be aligned in the second direction DR2. As described above, the first to third driver connection parts CD1 to CD3 may correspond to positions of connection transistors constituting the first to third pixel drivers PDC1 to PDC3, respectively. The connection transistor may be a transistor including, as one electrode, a connection node at which the pixel driver PDC (see FIG. 2A) or PDC-1 (see FIG. 2B) and the light-emitting device LD (see FIG. 2A or 2B) are connected in one pixel, and, for example, may correspond to the sixth transistor T6 of FIG. 2A or the first transistor T1 of FIG. 2B. According to an embodiment of the inventive concept, since a pixel driver is designed in the same manner for all pixels regardless of a shape, size, or emitted light color of an emission part, a process may be simplified and manufacturing cost may be reduced. The 1-1st driver connection part CD1a of the 1-1st connection line CN1a, the 2-1st driver connection part CD2a of the 2-1st connection line CN2a, and the 3-1st driver connection part CD3a of the 3-1st connection line CN3a may correspond to positions of connection transistors constituting the 1-1st to 3-1st pixel drivers PDC1a to PDC3a, respectively. The 1-2nd driver connection part CD1b of the 1-2nd connection line CN1b, the 2-2nd driver connection part CD2b of the 2-2nd connection line CN2b, and the 3-2nd driver connection part CD3b of the 3-2nd connection line CN3b may correspond to positions of connection transistors constituting the 1-2nd to 3-2nd pixel drivers PDC1b to PDC3b, respectively.

In one light-emitting unit, a plurality of emission connection parts CE may be arranged and the emission connection parts CE may include a first emission connection part CE1, a second emission connection part CE2, and a third emission connection part CE3. The first emission connection part CE1, the second emission connection part CE2, and the third emission connection part CE3 may be arranged spaced apart from the first driver connection part CD1, the second driver connection part CD2, and the third driver connection part CD3, respectively in a plan view.

In the present embodiment, the first to third emission connection parts CE1 to CE3 may be disposed at positions not overlapping the emission parts EP1 to EP3 in a plan view. The emission connection part CE of the connection line CN is a portion to which the light-emitting device LD (see FIG. 2A or 2B) is connected and in which a tip part TIP (see FIG. 5A) is formed and is thus disposed at a position not overlapping the emission opening OP-E (see FIG. 5A). That is, the opening regions OP of the separator SPR may include regions protruding from the emission parts EP1 to EP3, and the emission connection parts CE1 to CE3 may be disposed in the protruding regions. Therefore, the cathodes EL2_1 to EL2_3 May have protruding portions corresponding to the protruding regions of the opening regions OP, and may be connected through protruding portions to the connection lines CN1 to CN3 at positions in which the emission connection parts CE1 to CE3 are arranged. Therefore, an emission connection part that may be connected to a connection line may be provided without reducing an emission area size of an emission part.

As illustrated in FIG. 4B, the 1-1st to 3-1st opening regions OP1a, OP2a, and OP3a and the 1-2nd to 3-2nd opening regions OP1b, OP2b, and OP3b each may include a protruding region. The 1-1st emission connection part CE1a of the 1-1st connection line CN1a, the 2-1st emission connection part CE2a of the 2-1st connection line CN2a, and the 3-1st emission connection part CE3a of the 3-1st connection line CN3a may be arranged in the protruding regions of the 1-1st to 3-1st opening regions OP1a, OP2a, and OP3a, respectively. The 1-2nd emission connection part CE1b of the 1-2nd connection line CN1b, the 2-2nd emission connection part CE2b of the 2-2nd connection line CN2b, and the 3-2nd emission connection part CE3b of the 3-2nd connection line CN3b may be arranged in the protruding regions of the 1-2nd to 3-2nd opening regions OP1b, OP2b, and OP3b, respectively.

The 1-1st emission connection part CE1a may be arranged spaced apart from the 1-1st emission part EP1a in the second direction DR2, and the 1-2nd emission connection part CE1b may be arranged spaced apart from the 1-2nd emission part EP1b in an opposite direction to the second direction DR2. The 2-1st emission connection part CE2a may be arranged spaced apart from the 2-1st emission part EP2a in the first direction DR1, and the 2-2nd emission connection part CE2b may be arranged spaced apart from the 2-2nd emission part EP2b in an opposite direction to the first direction DR1. The 3-1st emission connection part CE3a may be arranged spaced apart from the 3-1st emission part EP3a in an opposite direction to the second direction DR2, and the 3-2nd emission connection part CE3b may be arranged spaced apart from the 3-2nd emission part EP3b in the second direction DR2.

In the present embodiment, the emission connection parts CE may be arranged adjacent to each other, thus forming contact groups CG. The contact groups CG may include first sub groups G1 and second sub groups G2.

The 1-1st opening region OP1a and the 1-2nd opening region OP1b may be arranged with the 2-1st opening region OP2a disposed therebetween so that a protruding portion of the 1-1st opening region OP1a and a protruding portion of the 1-2nd opening region OP1b protrude towards a protruding portion of the 2-1st opening region OP2a. Accordingly, the 1-1st emission connection part CE1a and the 2-1st emission connection part CE2a arranged in one light-emitting unit and the 1-2nd emission connection part CE1b arranged in another light-emitting unit adjacent thereto along the second direction DR2 may be arranged in the second direction DR2 and may provide the first sub group G1.

The 3-2nd opening region OP3b and the 3-1st opening region OP3a may be arranged with the 2-2nd opening region OP2b disposed therebetween so that a protruding portion of the 3-2nd opening region OP3b and a protruding portion of the 3-1st opening region OP3a protrude towards a protruding portion of the 2-2nd opening region OP2b. Accordingly, the 3-2nd emission connection part CE3b and the 2-2nd emission connection part CE2b arranged in one light-emitting unit and the 3-1st emission connection part CE3a arranged in another light-emitting unit adjacent thereto along the second direction DR2 may be arranged in the second direction DR2 and may provide the second sub group G2.

In the present embodiment, shapes and arrangement of connection lines CN-c arranged in the second-row first-column light-emitting unit UT21 may be the same as shapes and arrangement of the 1-2nd to 3-2nd connection lines CN1b, CN2b, and CN3b arranged in the first-row second-column light-emitting unit UT12. Likewise, shapes and arrangement of connection lines CN-d arranged in the second-row second-column light-emitting unit UT22 may be the same as shapes and arrangement of the 1-1st to 3-1st connection lines CN1a, CN2a, and CN3a arranged in the first-row first-column light-emitting unit UT11. Arrangement of the emission connection parts CE in the second row Rk+1 May be provided by shifting arrangement of the emission connection parts CE in the first row Rk one column in the second direction DR2

Accordingly, as illustrated in FIG. 4A, the first sub groups G1 and the second sub groups G2 may be alternately arranged in a row direction and in a column direction. The first sub group G1 and the second sub group G2 which are adjacent to each other may be arranged facing in the first direction DR. According to the present embodiment, since the emission connection parts CE are arranged adjacent to each other forming the contact group CG, an area that may be used as an emission area of an emission part may be increased, and thus a degree of design freedom of the emission part may be improved and a large size of the emission area of the emission part may be secured.

As illustrated in FIG. 4C, the first electrode EL1 (hereinafter anode) according to an embodiment of the inventive concept may be commonly provided to the plurality of emission parts EP1 to EP3. That is, the anode EL1 may be provided in an integrated form and arranged overlapping the emission parts EP1 to EP3 or the separator SPR. As described above, the first power supply voltage VDD (see FIG. 1) may be applied to the anode EL1, and a common voltage may be provided to all of the emission parts EP1 to EP3. The anode EL1 may be connected to the first power supply line VDL (see FIG. 2A) that provides the first power supply voltage VDD (see FIG. 1) in the peripheral area NDA (see FIG. 3A) or may be connected to the first power supply line VDL (see FIG. 2A) in the display area DA, and the connection configuration of the anode EL1 is not limited to a certain embodiment.

Meanwhile, a plurality of openings OP-EL1 may be defined in the anode EL1 according to an embodiment of the inventive concept, and the openings OP-EL may be formed through a layer of the anode EL1. The openings OP-EL1 may be arranged at a position not overlapping the emission parts EP, and may be generally disposed at a position overlapping the separator SPR. The openings OP-EL1 may facilitate discharge of gas generated in an organic layer arranged below the anode EL1, for example, the sixth insulating layer 60 (see FIG. 5A) that will be described later. Accordingly, gas may be sufficiently discharged from an organic layer arranged below a light-emitting device during a manufacturing process of the display panel DP (see FIG. 1), and gas discharged from an organic layer may be reduced after manufacturing, and thus a deterioration rate of the light-emitting device LD (see FIG. 2A or 2B) may reduce.

According to an embodiment of the inventive concept, since a connection line is arranged between a light-emitting device and a pixel driver, the light-emitting device may be easily connected to the pixel driver only by changing a shape of a cathode without changing shapes or arrangement of emission parts. Therefore, a degree of design freedom for arrangement of the pixel driver may be improved, and an area size of an emission part of the display panel or resolution thereof may be easily increased.

FIGS. 5A and 5B are enlarged cross-sectional views illustrating a partial region of a display panel, taken along line I-I′ of FIG. 4A, according to an embodiment of the inventive concept.

Referring to FIG. 5A, the display panel DP of an embodiment may include a display layer DPL and a sensing layer ISL arranged on the display layer DPL. The display layer DPL may include a base layer BS, a driving device layer DDL, a light-emitting device layer LDL, and an encapsulation layer ECL. The driving device layer DDL may include a plurality of insulating layers 10, 20, 30, 40, and 50 arranged on the base layer BS, and a plurality of conductive patterns and semiconductor patterns arranged between the insulating layers 10, 20, 30, 40, and 50. The conductive patterns and semiconductor patterns may be arranged between the insulating layers 10, 20, 30, 40, and 50 to constitute the pixel driver PDC. For ease of description, FIG. 5A illustrates a cross-section of a portion of a region in which one pixel is arranged.

The base layer BS may be a member that provides a base surface on which the pixel driver PDC is arranged. The base layer BS may be a rigid substrate or a flexible substrate that is bendable, foldable, or rollable. The base layer BS may be a glass substrate, a metal substrate, a polymer substrate, or the like. However, an embodiment of the inventive concept is not limited thereto, and the base layer BS may be an inorganic layer, an organic layer, or a composite material layer.

The base layer BS may have a multi-layer structure. The base layer BS may include a first polymer resin layer, a silicon oxide (SiOₓ) layer arranged on the first polymer resin layer, an amorphous silicon (a-Si) layer arranged on the silicon oxide layer, and a second polymer resin layer arranged on the amorphous silicon layer. The silicon oxide layer and the amorphous silicon layer may be referred to as a base barrier layer.

The polymer resin layers may include a polyimide-based resin. Furthermore, the polymer resin layers may include at least one of acrylate-based resin, methacrylate-based resin, polyisoprene-based resin, vinyl-based resin, epoxy-based resin, urethane-based resin, cellulose-based resin, siloxane-based resin, polyamide-based resin, or perylene-based resin. Herein, the term “. . . -based resin” indicates inclusion of a functional group of “. . . ”.

In the display panel DP, the insulating layers or conductive layers and semiconductor layers arranged on the base layer BS may be formed by coating or deposition. Thereafter, a hole may be formed in an insulating layer or a semiconductor pattern, a conductive pattern, a signal line, etc. may be formed by selectively patterning an organic layer, an inorganic layer, a semiconductor layer, and a conductive layer through photolithography processes.

The driving device layer DDL may include the first to fifth insulating layers 10 to 50 sequentially arranged on the base layer BS and the pixel driver PDC. FIG. 5A illustrates one transistor TR and two capacitors C1 and C2 of the pixel driver PDC. The transistor TR in FIG. 5A may be a transistor connected to the light-emitting device LD through the connection line CN, i.e., a connection transistor connected to a node (N4 of FIG. 2A or N2 of FIG. 2B) which is connected to the cathode EL2 of the light-emitting device LD, and may specifically correspond to the sixth transistor T6 of FIG. 2A or the first transistor T1 of FIG. 2B. Meanwhile, although not illustrated, other transistors constituting the pixel driver PDC may have the same structure as the transistor TR (hereinafter connection transistor) illustrated in FIG. 5A. However, this is merely an example, and the other transistors constituting the pixel driver PDC may have a different structure from that of the connection transistor TR and are not limited to a certain embodiment.

The first insulating layer 10 May be arranged on the base layer BS. The first insulating layer 10 May be an inorganic layer and/or organic layer and may have a single-layer or multi-layer structure. The first insulating layer 10 May include at least one of aluminum oxide, titanium oxide, silicon oxide, silicon nitride, silicon oxynitride, zirconium oxide, and hafnium oxide. In the present embodiment, the first insulating layer 10 is illustrated as a single layer of a silicon oxide layer. Meanwhile, the insulating layers that will be described hereinunder may be an inorganic layer and/or organic layer, and may have a single-layer or multi-layer structure. The inorganic layer may include at least one of the above-mentioned materials but is not limited thereto.

Meanwhile, the first insulating layer 10 May cover a bottom conductive layer BCL. That is, the display panel DP may further include the bottom conductive layer BCL arranged to overlap the connection transistor TR below the connection transistor TR. The bottom conductive layer BCL may prevent electric potential caused by a polarization phenomenon of the base layer BS from affecting the connection transistor TR. Furthermore, the bottom conductive layer BCL may block light that is incident on the connection transistor TR from below the bottom conductive layer BCL. The bottom conductive layer BCL may be completely overlapped with the semiconductor pattern SP. At least one of an inorganic layer or a buffer layer may be further arranged between the bottom conductive layer BCL and the base layer BS.

The bottom conductive layer BCL may include reflective metal. For example, the bottom conductive layer BCL may include titanium (Ti), molybdenum (Mo), alloys containing molybdenum, aluminum (Al), alloys containing aluminum, aluminum nitride (AlN), tungsten (W), tungsten nitride (WN), copper (Cu), and/or the like.

In an embodiment, the bottom conductive layer BCL may be connected to the source (or the source region SR of the semiconductor pattern SP) of the connection transistor TR. In this case, the bottom conductive layer BCL may have the same electric potential as the source of the connection transistor TR. However, an embodiment of the inventive concept is not limited thereto, and the bottom conductive layer BCL may be connected to the gate (or gate electrode GE) of the connection transistor TR and may have the same electric potential as the gate. Alternatively, the bottom conductive layer BCL may be connected to another electrode and may independently receive a constant voltage or pulse signal. Alternatively, the bottom conductive layer BCL may be provided in a form isolated from another conductive pattern. The bottom conductive layer BCL according to an embodiment of the inventive concept may be provided in various forms and the configuration of the bottom conductive layer BCL is not limited to a certain embodiment.

The connection transistor TR is arranged on the first insulating layer 10. The connection transistor TR may include a semiconductor pattern SP and a gate electrode GE. The semiconductor pattern SP may be arranged on the first insulating layer 10. The semiconductor pattern SP may include an oxide semiconductor. For example, the oxide semiconductor may include transparent conductive oxide (TCO) such as indium tin oxide (ITO), indium zinc oxide (IZO), indium gallium zinc oxide (IGZO), zinc oxide (ZnO) or indium oxide (In₂O₃). However, an embodiment of the inventive concept is not limited thereto, and the semiconductor pattern may include amorphous silicon, low-temperature polycrystalline silicon, or polycrystalline silicon.

The second insulating layer 20 May commonly overlap a plurality of pixels, and may cover the semiconductor pattern SP. The second insulating layer 20 May be an inorganic layer and/or organic layer and may have a single-layer or multi-layer structure. The second insulating layer 20 May include at least one of aluminum oxide, titanium oxide, silicon oxide, silicon nitride, silicon oxynitride, zirconium oxide, and hafnium oxide. In the present embodiment, the second insulating layer 20 May be a single layer of a silicon oxide layer.

The semiconductor pattern SP may include a source region SR, a drain region DR, and a channel region CR (or active region) which is distinguished according to a degree of conductivity. The channel region CR may be a portion overlapping the gate electrode GE in a plan view. The source region SR and the drain region DR may be spaced apart from each other with the channel region CR disposed therebetween. In the case where the semiconductor pattern SP is an oxide semiconductor, the source region SR and the drain region DR each may be a reduced region. Accordingly, the source region SR and the drain region DR have relatively high reducible metal content compared to the channel region CR. Alternatively, in the case where the semiconductor pattern SP is polycrystalline silicon, the source region SR and the drain region DR each may be a region doped with dopants at high concentration.

The source region SR and the drain region DR may have relatively high conductivity compared to the channel region CR. The source region SR may correspond to the source electrode of the connection transistor TR, and the drain region DR may correspond to the drain electrode of the connection transistor TR. As illustrated in FIG. 5A, a source electrode pattern W1 and a drain electrode pattern W2 may be further provided, and the source electrode pattern W1 and the drain electrode pattern W2 may be connected to the source region SR and the drain region DR of the connection transistor TR, respectively. In detail, the additional source electrode pattern W1 and drain electrode pattern W2 may be integrally formed with one of lines constituting the pixel driver PDC and the method of forming the additional source electrode pattern W1 and drain electrode pattern W2 are not limited to a certain embodiment.

The gate electrode GE is arranged on the second insulating layer 20. The gate electrode GE may correspond to the gate of the connection transistor TR. The gate electrode GE may be arranged on the semiconductor pattern SP with the second insulating layer 20 disposed therebetween. However, this is merely an example, and the gate electrode GE may also be arranged below the semiconductor pattern SP and the configuration of the gate electrode GE is not limited to a certain embodiment.

The gate electrode GE may include titanium (Ti), silver (Ag), molybdenum (Mo), aluminum (Al), aluminum nitride (AlN), tungsten (W), tungsten nitride (WN), copper (Cu), or an alloy thereof, but the material forming the gate electrode GE is not particularly limited thereto.

A first capacitor electrode CPE1 and a second capacitor electrode CPE2 constitute the first capacitor C1. The first capacitor electrode CPE1 and the second capacitor electrode CPE2 may be spaced apart from each other with the first insulating layer 10 and the second insulating layer 20 disposed therebetween.

In the present embodiment, the first capacitor electrode CPE1 and the bottom conductive layer BCL may have an integrated form. Furthermore, the second capacitor electrode CPE2 and the gate electrode GE may also have an integrated form.

A third capacitor electrode CPE3 may be arranged on the third insulating layer 30. The third capacitor electrode CPE3 may be spaced apart from and overlap with the second capacitor electrode CPE2 in a plan view with the third insulating layer 30 disposed therebetween. The third capacitor electrode CPE3 may constitute the second capacitor C2 with the second capacitor electrode CPE2.

The fourth insulating layer 40 May be arranged on the third capacitor electrode CPE3.

The source electrode pattern W1 and the drain electrode pattern W2 may be arranged on the fourth insulating layer 40. The source electrode pattern W1 may be connected to the source region SR of the connection transistor TR through a first contact hole CNT1, and the source electrode pattern W1 and the source region SR of the semiconductor pattern SP may function as the source of the connection transistor TR. The drain electrode pattern W2 may be connected to the drain region DR of the connection transistor TR through a second contact hole CNT2, and the drain electrode pattern W2 and the drain region DR of the semiconductor pattern SP may function as the drain of the connection transistor TR.

The fifth insulating layer 50 May be arranged on the source electrode pattern W1 and the drain electrode pattern W2. The connection line CN may be arranged on the fifth insulating layer 50. The connection line CN connects the connection transistor TR and the light-emitting device LD. The connection line CN may be a connection node connecting the pixel driver PDC and the light-emitting device LD. That is, the connection line CN may correspond to the fourth node N4 illustrated in FIG. 2A or the second node N2 illustrated in FIG. 2B. This is merely an example, and provided that the connection line CN is connectable to the light-emitting device LD, the connection line CN may be defined as a connection node to various elements among elements constituting the pixel driver PDC according to design of the pixel driver PDC and is not limited to a certain embodiment.

The connection line CN may have a triple-layer structure. In detail, the connection line CN may include a first layer L1, a second layer L2, and a third layer L3 sequentially laminated in a third direction DR3.

The first and third layers L1 and L3 each may have a relatively thin thickness compared to the second layer L2. The first and third layers L1 and L3 may include the same material, and the second layer L2 may include a material different from the material of the first and third layers L1 and L3. An etch rate of the second layer L2 may be higher than an etch rate of each of the first and third layers L1 and L3 to an etchant which etches materials constituting the connection line CN. That is, the second layer L2 may include a material having higher etch rate than the first and third layers L1 and L3 to the etchant. For example, the first and third layers L1 and L3 each may include titanium (Ti), and the second layer L2 may include aluminum (Al). However, the materials of the first to third layers L1 to L3 are not limited to a certain embodiment.

A side surface of the third layer L3 may protrude outwards from a side surface of the second layer L2. That is, the side surface of the second layer L2 is arranged inwards compared to the side surface of the third layer L3 to form an undercut portion in the second layer L2 or overhang portion in the third layer L3. The overhang portion (herein after a tip part TIP) of the connection line CN may be a portion of the third layer L3 protruding further than the second layer L2.

The sixth insulating layer 60 May be arranged between the driving device layer DDL and the light-emitting device layer LDL. The sixth insulating layer 60 is arranged on the fifth insulating layer 50 and covers the connection line CN. The fifth insulating layer 50 and the sixth insulating layer 60 each may be an organic layer. For example, the fifth insulating layer 50 and the sixth insulating layer 60 each may include benzocyclobutene (BCB), polyimide, hexamethyldisiloxane (HMDSO), polymethylmethacrylate (PMMA), a general-purpose polymer such as polystyrene (PS), a polymer derivative having a phenol group, an acrylic polymer, an imidic polymer, an arylether polymer, an amidic polymer, a fluoric polymer, a p-xylene polymer, a vinyl alcohol polymer, or a blend thereof.

A first contact opening OP1-C that exposes at least a portion of the connection line CN may be defined in the sixth insulating layer 60. In detail, the side surface of the third layer L3 in which the tip part TIP is formed and the side surface of each of the first and second layers L1 and L2 adjacent thereto may be exposed from the sixth insulating layer 60.

The connection line CN may be connected to the connection transistor TR through a contact hole formed through the fifth insulating layer 50, and may be connected to the light-emitting device LD of the light-emitting device layer LDL to an exposed portion of the connection line CN. That is, the connection line CN connects the connection transistor TR and the light-emitting device LD. Relevant detailed descriptions will be provided later.

Meanwhile, in the display panel DP according to an embodiment of the inventive concept, the sixth insulating layer 60 May be omitted or provided in plurality and the configuration of the sixth insulating layer 60 is not limited to a certain embodiment.

The light-emitting device layer LDL may be arranged on the sixth insulating layer 60. The light-emitting device layer LDL may include a pixel defining layer PDL, the light-emitting device LD, and the separator SPR.

The pixel defining layer PDL may be an organic layer. For example, the pixel defining layer PDL may include benzocyclobutene (BCB), polyimide, hexamethyldisiloxane (HMDSO), polymethylmethacrylate (PMMA), a general-purpose polymer such as polystyrene (PS), a polymer derivative having a phenol group, an acrylic polymer, an imidic polymer, an arylether polymer, an amidic polymer, a fluoric polymer, a p-xylene polymer, a vinyl alcohol polymer, or a blend thereof.

In an embodiment, the pixel defining layer PDL may have a property of absorbing light and may have, for example, black color. The pixel defining layer PDL may include a black coloring agent. The black coloring agent may include a black dye or black pigment. The black coloring agent may include metals such as carbon black and chromium or oxides thereof. The pixel defining layer PDL may correspond to a light shielding pattern having a light shielding characteristic.

An emission opening OP-E may be formed through the pixel defining layer PDL. The emission opening OP-E may be provided in plurality and arranged in a region corresponding to each of light-emitting regions. The emission opening OP-E may be a region in which all of components of the light-emitting device LD overlap and may be substantially a region in which light emitted from the light-emitting device LD is displayed. Accordingly, a shape of the above-mentioned emission part EP (see FIG. 3A) may substantially correspond to a shape of the emission opening OP-E in a plan view.

In the present embodiment, a second contact opening OP2-C extending to the first contact opening OP1-C may be defined in the pixel defining layer PDL. The second contact opening OP2-C may be spaced apart from the emission opening OP-E. A planar area size of the second contact opening OP2-C may be larger than or equal to a planar area size of the first contact opening OP1-C. The side surface of the third layer L3 in which the tip part TIP is formed and the side surface of each of the first and second layers L1 and L2 adjacent thereto may not be covered by the pixel defining layer PDL.

The light-emitting device LD may include a first electrode EL1, an intermediate layer IML, and a second electrode EL2. The first electrode EL1 may be a translucent, transmissive, or reflective electrode. According to an embodiment of the inventive concept, the first electrode EL1 may include a reflective layer formed of silver (Ag), magnesium (Mg), aluminum (Al), platinum (Pt), palladium (Pd), gold (Au), nickel (Ni), neodymium (Nd), iridium (Ir), chromium (Cr) or a compound thereof, and a transparent or semitransparent electrode layer formed on the reflective layer. The transparent or semitransparent electrode layer may include at least one selected from the group consisting of indium tin oxide (ITO), indium zinc oxide (IZO), indium gallium zinc oxide (IGZO), zinc oxide (ZnO), indium oxide (In₂O₃), and aluminum doped zinc oxide (AZO). For example, the first electrode EL1 may include a laminate structure of ITO/Ag/ITO.

In the present embodiment, the first electrode EL1 may be the anode of the light-emitting device LD and may correspond to the anode EL1 described above with reference to FIG. 4C. That is, the first electrode EL1 may be connected to the first power supply line VDL (see FIG. 2A) and may receive the first power supply voltage VDD (see FIG. 2A). The first electrode EL1 may be connected to the first power supply line VDL (see FIG. 2A) in the display area DA (see FIG. 3A) or may be connected to the first power supply line VDL (see FIG. 2A) in the peripheral area NDA (see FIG. 3A). In the latter case, the first power supply line VDL (see FIG. 2A) may be arranged in the peripheral area NDA (see FIG. 3A) and the first electrode EL1 may have a shape extending to the peripheral area NDA (see FIG. 3A).

In the present embodiment, the first electrode EL1 is illustrated as overlapped with the emission opening OP-E and not overlapped with the separator SPR but the configuration of the first electrode EL1 is not limited thereto. The first electrode of a pixel may have an integrated shape and may have a mesh or lattice shape in which openings are defined in a partial region. That is, provided that the same first power supply voltage VDD (see FIG. 2A) is applied to the first electrode EL1 of a plurality of light-emitting devices, a shape of the first electrode EL1 may be variously provided and is not limited to a certain embodiment.

The intermediate layer IML is arranged between the first electrode EL1 and the second electrode EL2. The intermediate layer IML may include an emitting layer EML and a functional layer FNL. However, this is merely an example, and the light-emitting device LD may include the intermediate layer IML of various structures and the structures of the intermediate layer IML is not limited to a certain embodiment. For example, the functional layer FNL may be provided as a plurality of layers or may be provided as two or more layers spaced apart from each other with the emitting layer EML disposed therebetween. Alternatively, in an embodiment of the inventive concept, the functional layer FNL may be omitted.

The emitting layer EML may emit light by absorbing energy corresponding to a potential difference between the first electrode EL1 and the second electrode EL2. The emitting layer EML is illustrated as including an organic light-emitting material, but is not limited thereto, and thus may include an inorganic light-emitting material or may be provided as a mixture layer of an organic light-emitting material and an inorganic light-emitting material.

The emitting layer EML may be arranged to cover the emission opening OP-E. In the present embodiment, the emitting layer EML may be separately formed in each pixel. In the case where the emitting layer EML is separately formed in each of the emission parts EP (see FIG. 3A), the emitting layer EML may emit light having at least any one of red color, green color, or blue color. However, an embodiment of the inventive concept is not limited thereto, and the emitting layer EML may have an integrated shape commonly provided to adjacent emission parts EP (see FIG. 3A). In this case, the emitting layer EML may emit blue light or white light. Meanwhile, the emitting layer EML may have the same shape as the functional layer FNL and may also be provided as the intermediate layer IML having an integrated form with the functional layer FNL without a boundary between the emitting layer EML and the functional layer FNL.

The functional layer FNL may be arranged between the first electrode EL1 and the second electrode EL2. In detail, the functional layer FNL may be arranged between the first electrode EL1 and the emitting layer EML or between the second electrode EL2 and the emitting layer EML. Alternatively, the functional layer FNL may be arranged between the first electrode EL1 and the emitting layer EML and between the second electrode EL2 and the emitting layer EML. In the present embodiment, the emitting layer EML is illustrated as being inserted into the functional layer FNL. However, this is merely an example, and the functional layer FNL may include a layer arranged between the emitting layer EML and the first electrode EL1 and/or a layer arranged between the emitting layer EML and the second electrode EL2 or may be provided in plurality for each of the arranged layers and the configuration of the functional layer FNL is not limited to a certain embodiment.

The functional layer FNL may control movement of charge. The functional layer FNL may include a hole injection/transport material and/or an electron injection/transport material. The functional layer FNL may include at least one of an electron blocking layer, a hole transport layer, a hole injection layer, a hole blocking layer, an electron transport layer, an electron injection layer, or a charge generation layer.

The second electrode EL2 may be arranged on the intermediate layer IML. As described above, the second electrode EL2 is connected to the pixel driver PDC through the fourth node N4 of FIG. 2A or the second node N2 of FIG. 2B. In the present embodiment, the second electrode EL2 may be electrically connected to the connection transistor TR through the connection line CN.

The connection line CN may include the driver connection part CD and the emission connection part CE. For ease of description, FIG. 5A illustrates the driver connection part CD and the emission connection part CE but does not illustrate the other portion of the connection line CN connecting the driver connection part CD and the emission connection part CE.

The driver connection part CD may be a portion of the connection line CN connected to the pixel driver PDC and may be substantially a portion connected to the connection transistor TR. In the present embodiment, the driver connection part CD may extend through the fifth insulating layer 50 and is connected to the drain region DR of the semiconductor pattern SP through the drain electrode pattern W2 of the connection transistor TR.

The emission connection part CE may be a portion of the connection line CN connected to the light-emitting device LD. One side of the connection line CN may not be covered by the sixth insulating layer 60 and the pixel defining layer PDL. The emission connection part CE may be a portion of the connection line CN which is not covered by the sixth insulating layer 60 and the pixel defining layer PDL and directly connected to the second electrode EL2. In detail, the second electrode EL2 may be connected to a side surface of the second layer L2 which is not covered by the sixth insulating layer 60.

The intermediate layer IML may be arranged on the pixel defining layer PDL. The intermediate layer IML may also be arranged on a portion of the sixth insulating layer 60 not covered by the pixel defining layer PDL. Furthermore, the intermediate layer IML may also be arranged on a portion of the connection line CN not covered by the sixth insulating layer 60.

The intermediate layer IML may include one end arranged on an upper surface of the fifth insulating layer 50 and another end arranged on an upper surface of the tip part TIP of the connection line CN. That is, in a cross-sectional view, the intermediate layer IML may have a shape that is partially disconnected from the tip part TIP in a region in which the emission connection part CE is defined. However, in a plan view, the intermediate layer IML may have an integrated shape that is overall connected in a region defined by a closed line by the separator SPR.

The second electrode EL2 may include one end arranged on an upper surface of the fifth insulating layer 50 and another end arranged on an upper surface of the tip part TIP of the connection line CN. That is, in a cross-sectional view, the second electrode EL2 may have a shape that is partially disconnected from the tip part TIP in a region in which the emission connection part CE is defined. However, in a plan view, the second electrode EL2 may have an integrated shape that is overall connected in a region defined by a closed line by the separator SPR.

One end of the second electrode EL2 may be arranged along a side surface of the second layer L2 in contact with the side surface of the second layer L2. In detail, due to a deposition angle difference between the second electrode EL2 and the intermediate layer IML, the second electrode EL2 may be formed to contact the side surface of the second layer L2 not covered by the intermediate layer IML due to the tip part TIP. That is, the second electrode EL2 may be connected to the connection line CN without an additional patterning process for the intermediate layer IML, and thus the light-emitting device LD may be electrically connected to the pixel driver PDC through the connection line CN.

In the present embodiment, the separator SPR may be arranged on the pixel defining layer PDL. The separator SPR may have a multi-layer structure including at least one of an organic material, metal, or transparent electrode. In an embodiment, the second electrode EL2 and the intermediate layer IML may be formed by being commonly deposited in a plurality of pixels through an open mask. Here, the second electrode EL2 may be disconnected due to the separator SPR surrounding each emission part EP (see FIG. 3A). That is, the second electrode EL2 may be electrically disconnected from second electrodes disposed in adjacent pixels.

The separator SPR may have a reversely tapered shape. That is, an internal angle θ1 formed by an upper surface of the pixel defining layer PDL (or lower surface of the separator SPR) and an inner surface IS of the separator SPR may be an obtuse angle. However, this is merely an example, and provided that the separator SPR electrically disconnects the second electrode EL2 for each pixel, the internal angle θ1 formed by the upper surface of the pixel defining layer PDL and the inner surface IS of the separator SPR may be variously set.

The separator SPR may include an organic material, thus having an insulating property. A deposited layer, i.e., the intermediate layer IML and the second electrode EL2, may be disconnected due to the separator SPR having the reversely tapered shape. The intermediate layer IML and the second electrode EL2 may be separated due to the separator SPR from the intermediate layer IML and the second electrode EL2 included in adjacent pixels.

Disconnected portions may be formed in the deposited layer due to the separator SPR. One end portion of the disconnected deposited layer may be spaced apart from the separator SPR and disposed on the pixel defining layer PDL, and the other end portion of the disconnected deposited layer may cover the inner surface IS of the separator SPR. Even if the end portions are physically connected without being separated in the deposited layer, the deposited layer may be considered to be disconnected due to the separator SPR if an electrical connection is not established between the deposited layer positioned on the pixel defining layer PDL and the deposited layer arranged on the inner surface IS of the separator SPR since the deposited layer is formed to a thin thickness along the inner surface IS of the separator SPR.

A first dummy pattern layer UP1 and a second dummy pattern layer UP2 may be arranged on the separator SPR.

The first dummy pattern layer UP1 may be arranged on an upper surface US and the inner surface IS of the separator SPR. The first dummy pattern layer UP1 may include the same material as the intermediate layer IML. The first dummy pattern layer UP1 may correspond to a residue separated from the intermediate layer IML due to the separator SPR when the intermediate layer IML is commonly formed.

The second dummy pattern layer UP2 may include the same material as the second electrode EL2. The second dummy pattern layer UP2 may correspond to a residue separated from the second electrode EL2 due to the separator SPR when the second electrode EL2 is commonly formed.

According to an embodiment of the inventive concept, even if an additional patterning process is not performed using a mask, the second electrode EL2 or the intermediate layer IML is not formed or is formed to a thin thickness on the inner surface IS of the separator SPR during a process of forming the second electrode EL and the intermediate layer IML, and thus the second electrode EL and the intermediate layer IML may be easily disconnected for each pixel. However, this is merely an example, and provided that the second electrode EL2 and the intermediate layer IML are disconnected, a shape of the separator SPR may be variously changed and the configuration of the separator SPR is not limited to a certain embodiment.

The encapsulation layer ECL may be arranged on the pixel defining layer PDL and cover the separator SPR. The encapsulation layer ECL may include a first inorganic layer IL1, an organic layer OL, and a second inorganic layer IL2 sequentially laminated. However, an embodiment of the inventive concept is not limited thereto, and the encapsulation layer ECL may further include a plurality of inorganic layers and organic layers.

The first and second inorganic layers IL 1 and IL 2 May protect the light-emitting device layer LDL from moisture and oxygen, and the organic layer OL may protect the-emitting device layer LDL from foreign matter such as particles of dust. The first and second inorganic layers IL 1 and IL 2 May include a silicon nitride layer, a silicon oxynitride layer, a silicon oxide layer, a titanium oxide layer, an aluminum oxide layer, or the like. The organic layer OL may include an acrylic organic layer but is not limited thereto.

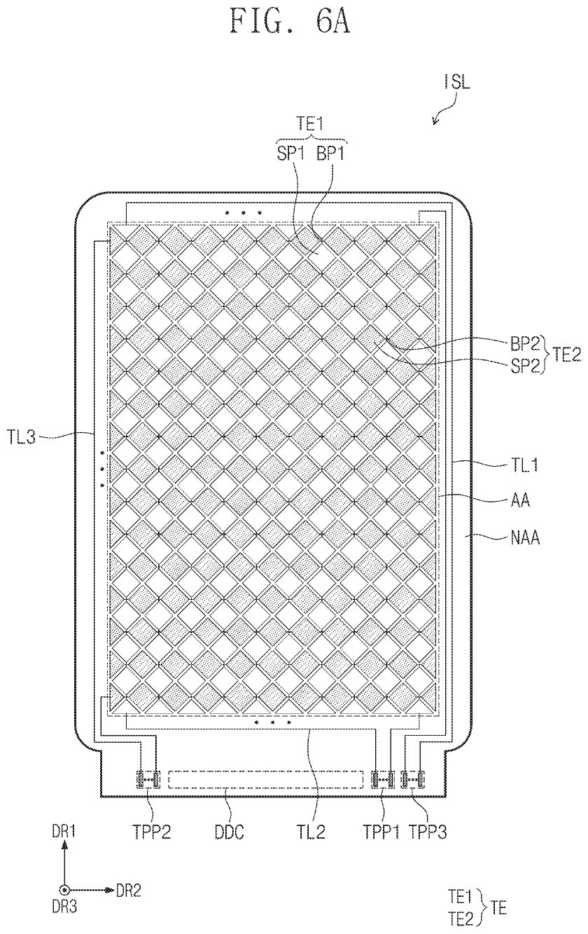

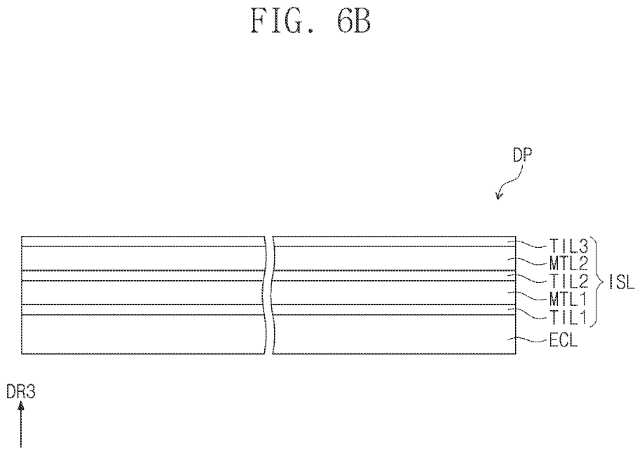

The sensing layer ISL senses an external input. In the present embodiment, the sensing layer ISL may be formed on the encapsulation layer ECL through a continuous process. Here, the sensing layer ISL may be expressed as being directly arranged on the encapsulation layer ECL. “Being directly arranged” May indicate that another component is not arranged between the sensing layer ISL and the encapsulation layer ECL. That is, an additional adhesive member may not be arranged between the sensing layer ISL and the encapsulation layer ECL. However, this is merely an example, and in the display device DD (see FIG. 1) according to an embodiment of the inventive concept, the sensing layer ISL may be provided after being separately formed or may be bonded to the encapsulation layer through an adhesive member and is not limited to a certain embodiment. The sensing layer ISL will be described in detail with reference to FIGS. 6A to 12.

FIG. 5B is a cross-sectional view illustrating a display panel according to an embodiment of the inventive concept. For ease of description, FIG. 5 illustrates a cross-section of a region corresponding to FIG. 5A. The same reference signs will be used for the same components as described above with reference to FIGS. 1 to 5A and overlapping descriptions will not be provided.

Referring to FIG. 5B, the display panel DP-1 of an embodiment may include the display layer DPL-1 and the sensing layer ISL arranged on the display layer DPL-1. The display panel DP-1 illustrates in FIG. 5B may further include a capping pattern CPP compared to the display panel DP illustrated in FIG. 5A. The capping pattern CPP may be arranged on the sixth insulating layer 60. Furthermore, the capping pattern CPP may also be arranged on a portion of the connection line CN not covered by the sixth insulating layer 60. The capping pattern CPP may be arranged to overlap the connection line CN, more specifically the emission connection part CE and/or the tip part TIP.

Furthermore, as illustrated in FIG. 5B, in a cross-sectional view, the capping pattern CPP may be disconnected under the tip part TIP in which the emission connection part CE is disposed. However, in a plan view, the capping pattern CPP may have an integrated shape that is overall connected in opening regions OP (see FIG. 4A) defined in the separator SPR. Meanwhile, one end of the partially disconnected capping pattern CPP may contact a side surface of the second layer L2 of the connection line CN, and another end of the capping pattern CPP may be arranged on the third layer L3 of the connection line CN and cover the tip part TIP.

The capping pattern CPP may include a conductive material. Accordingly, the second electrode EL2 may be electrically connected to the connection line CN through the capping pattern CPP. That is, the capping pattern CPP contacts the side surface of the second layer L2 of the connection line CN, and the second electrode EL2 contacts the capping pattern CPP, so that all of the foregoing components may be electrically connected. The capping pattern CPP may cover a side surface of the second layer L2 of the connection line CN, and the second electrode EL2 may be electrically connected to the second layer L2 via the capping pattern CPP instead of directly contacting the side surface of the second layer L2, and thus a connection between the connection line CN and the second electrode E2 may be more easily established.

Furthermore, the capping pattern CPP may include a material having relatively low reactivity compared to the second layer L2 of the connection line CN. For example, the capping pattern CPP may include copper (Cu), silver (Ag), transparent conductive oxide, or the like. Since the side surface of the second layer L2 of the connection line CN is protected by the capping pattern CPP having relatively low reactivity, oxidation of a material included in the second layer L2 may be prevented. Furthermore, during an etching process for patterning the first electrode EL1, a phenomenon in which silver (Ag) components included in the first electrode EL1 are reduced and remain as particles that cause defect may be prevented.

In an embodiment, the capping pattern CPP may be formed through the same process as the first electrode EL1 and may include the same material as the first electrode EL1. However, this is merely an example, and the capping pattern CPP may be formed through a process different from that of the first electrode EL1 and may include a different material, and the material for the capping pattern CPP is not limited to a certain embodiment.

FIG. 6A is a plan view illustrating a sensing layer according to an embodiment of the inventive concept. FIG. 6B is a cross-sectional view illustrating some components of a display panel according to an embodiment of the inventive concept. FIG. 6B schematically illustrates cross-sections of the encapsulation layer ECL and the sensing layer ISL.

Referring to FIG. 6A, the sensing layer ISL of an embodiment may include a sensing area AA and a peripheral area NAA. The sensing area AA, in which an external input is sensed, may overlap the display area DA of FIG. 3A.

The sensing layer ISL may include a sensing electrode TE, trace lines TL1, TL2, and TL3, and sensor pad parts TPP1, TPP2, and TPP3.

In the present embodiment, the sensing electrode TE may include a first sensing electrode TE1 and a second sensing electrode TE2.

The first sensing electrode TE1 may extend in the first direction DR1. The first sensing electrode TE1 may be provided in plurality and arranged in the second direction DR2. The first sensing electrodes TE1 each may include a plurality of first sensing patterns SP1 arranged in the first direction DR1 and first intermediate patterns BP1 arranged between the first sensing patterns SP1.

The second sensing electrode TE2 may be electrically insulated from the first sensing electrode TE1 and may be driven independent of the first sensing electrode TE1. The second sensing electrode TE2 may extend in the second direction DR2. The second sensing electrode TE2 may be provided in plurality and arranged in the first direction DR1. The second sensing electrodes TE2 may be arranged so as to insulatively intersect the first sensing electrodes TE1. The second sensing electrodes TE2 each may include a plurality of second sensing patterns SP2 arranged in the second direction DR2 and second intermediate patterns BP2 arranged between the second sensing patterns SP2.

The sensing layer ISL may be driven in a mutual capacitive manner in which the first sensing electrodes TE1 and the second sensing electrodes TE2 receive different electrical signals or in a self capacitive manner in which the first sensing electrodes TE1 and the second sensing electrodes TE2 receive the same electrical signal. Alternatively, the sensing layer ISL may be driven in a resistive manner in which an external input is sensed through a resistance change in each of the first sensing electrodes TE1 and the second sensing electrodes TE2. Provided that an external input can be sensed through the first sensing electrodes TE1 and the second sensing electrodes TE2, the sensing layer ISL may be drive in various manners and is not limited to a certain embodiment.

The trace lines TL1 to TL3 may include first trace lines TL1 and TL2 connected to a corresponding first sensing electrode among the first sensing electrodes TE1 and second trace lines TL3 connected to a corresponding second sensing electrode among the second sensing electrodes TE2.

The first trace lines TL1 and TL2 may include 1-1st trace lines TL1 and 1-2nd trace lines TL2. The 1-1st trace lines TL1 may be connected to one ends of the first sensing electrodes TE1 arranged at an upper end, and the 1-2nd trace lines TL2 may be connected to other ends of the first sensing electrodes TE1 arranged at a lower end. The second trace lines TL3 may be connected to one ends of the second sensing electrodes TE2. The trace lines TL1 to TL3 may be respectively connected to corresponding sensor pads in the sensor pad parts TPP1 to TPP3.

A connection relationship between the trace lines TL1 to TL3 and the sensing electrodes TE1 and TE2 is not limited thereto and may be configured in various forms and is not limited to a certain embodiment.

Referring to FIGS. 6A and 6B, the sensing layer ISL according to the present embodiment may include a plurality of conductive layers and a plurality of sensing insulating layers. The sensing insulating layers may include first to third sensing insulating layers TIL1 to TIL3 sequentially laminated on the encapsulation layer ECL. However, this is merely an example, and the number of insulating layers constituting the sensing insulating layers is not limited to a certain embodiment.

The first sensing insulating layer TIL1 may be an inorganic layer including at least one of silicon nitride, silicon oxynitride, and silicon oxide. Alternatively, the first sensing insulating layer TIL1 may be an organic layer including epoxy-based resin, acryl-based resin, or imide-based resin. The first sensing insulating layer TIL1 may have a single-layer structure, or may have a multi-layer structure laminated along the third direction DR3.

The conductive layers may include a first conductive layer MTL1 and a second conductive layer MTL2. The first conductive layer MTL1 may be arranged on the first sensing insulating layer TIL1 and covered by the second sensing insulating layer TIL2, and the second conductive layer MTL2 may be arranged on the second sensing insulating layer TIL2 and covered by the third sensing insulating layer TIL3. A portion of the second conductive layer MTL2 may be connected to the first conductive layer MTL1 through a contact hole formed in the second sensing insulating layer TIL2. The conductive layers each may have a single-layer structure, or may have a multi-layer structure laminated along the third direction DR3.

A conductive layer having a single-layer structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), or indium zinc tin oxide (IZTO). In addition, the transparent conductive layer may include a conductive polymer such as poly(3,4-ethylenedioxythiophene) (PEDOT), metal nanowire, graphene, or the like.

A conductive layer having a multi-layer structure may include metal layers. The metal layers may have, for example, a triple-layer structure of titanium/aluminum/titanium. The conductive layer having a multi-layer structure may include at least one metal layer and at least one transparent conductive layer.

The first conductive layer MTL1 and the second conductive layer MTL2 each may include a transparent conductive oxide and/or may include a mesh shaped opaque conductive material. The first conductive layer MTL1 and the second conductive layer MTL2 may have various materials and shapes provided that visibility of an image displayed by light generated by the light-emitting device layer LDL (see FIGS. 5A and 5B) does not deteriorate and the configuration of the first conductive layer MTL1 and the second conductive layer MTL2 are not limited to a certain embodiment.

Components included in the first sensing electrode TE1 and the second sensing electrode TE2 may be included in either the first conductive layer MTL1 or the second conductive layer MTL2.

According to the present embodiment, the first sensing patterns SP1 and first intermediate patterns BP1 of the first sensing electrode TE1 and the second sensing patterns SP2 of the second sensing electrode TE2 may be arranged on the same layer, and the second intermediate patterns BP2 of the second sensing electrode TE2 may be arranged on a layer different from that of the first sensing patterns SP1 and first intermediate patterns BP1 of the first sensing electrode TE1 and the second sensing patterns SP2 of the second sensing electrode TE2. In the present embodiment, the first sensing patterns SP1, the first intermediate patterns BP1, and the second sensing patterns SP2 may be included in the second conductive layer MTL2, and the second intermediate patterns BP2 may be included in the first conductive layer MTL1.

The trace lines TL1 to TL3 may include at least one of the first conductive layer MTL1 and the second conductive layer MTL2. For example, the trace lines TL1 to TL3 may include one of the first conductive layer MTL1 and the second conductive layer MTL2, or may include two layers included in both the first conductive layer MTL1 and the second conductive layer MTL2, and the configuration of the trace lines TL1 to TL3 are not limited to a certain embodiment.

At least one of the second sensing insulating layer TIL2 or the third sensing insulating layer TIL3 may include an inorganic layer. The inorganic layer may include at least one of aluminum oxide, titanium oxide, silicon oxide, silicon nitride, silicon oxynitride, zirconium oxide, and hafnium oxide.

Alternatively, at least one of the second sensing insulating layer TIL2 and the third sensing insulating layer TIL3 may include an organic layer. The organic layer may include at least one of acrylic-based resin, methacrylic-based resin, polyisoprene-based resin, vinyl-based resin, epoxy-based resin, urethane-based resin, cellulose-based, siloxane-based resin, polyimide-based resin, polyamide-based resin, and perylene-based resin.

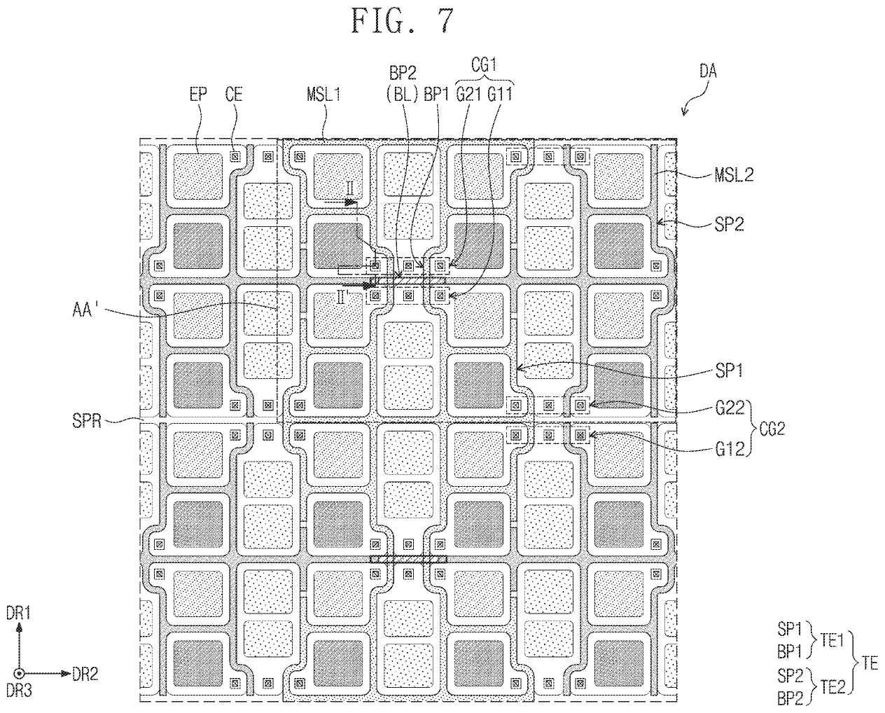

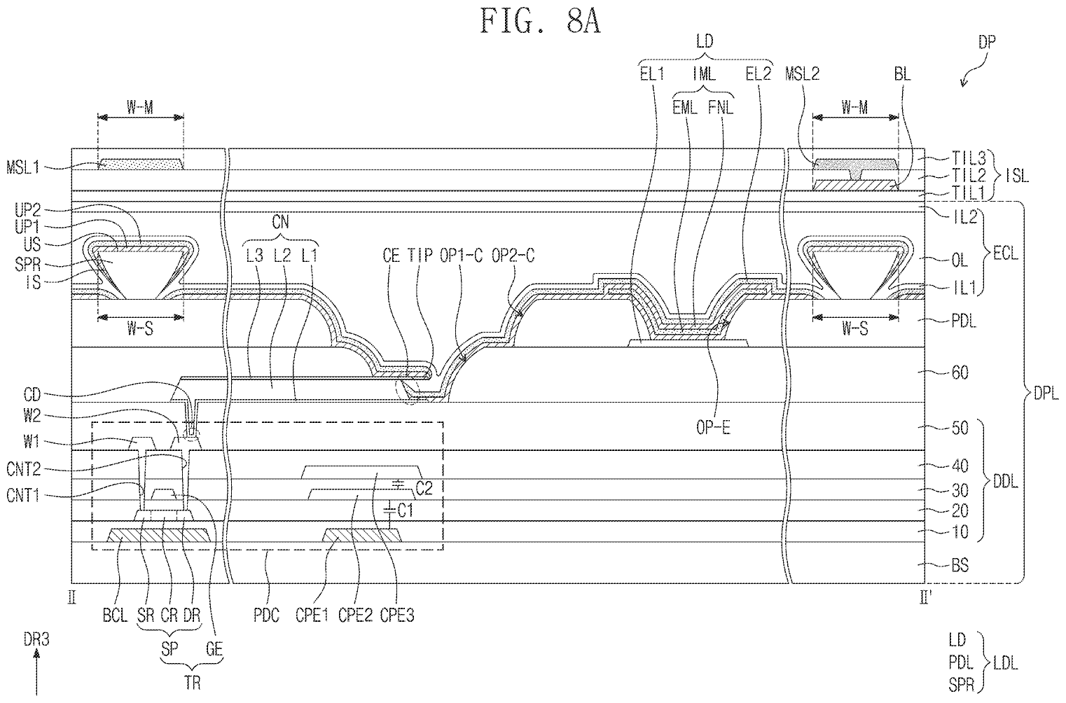

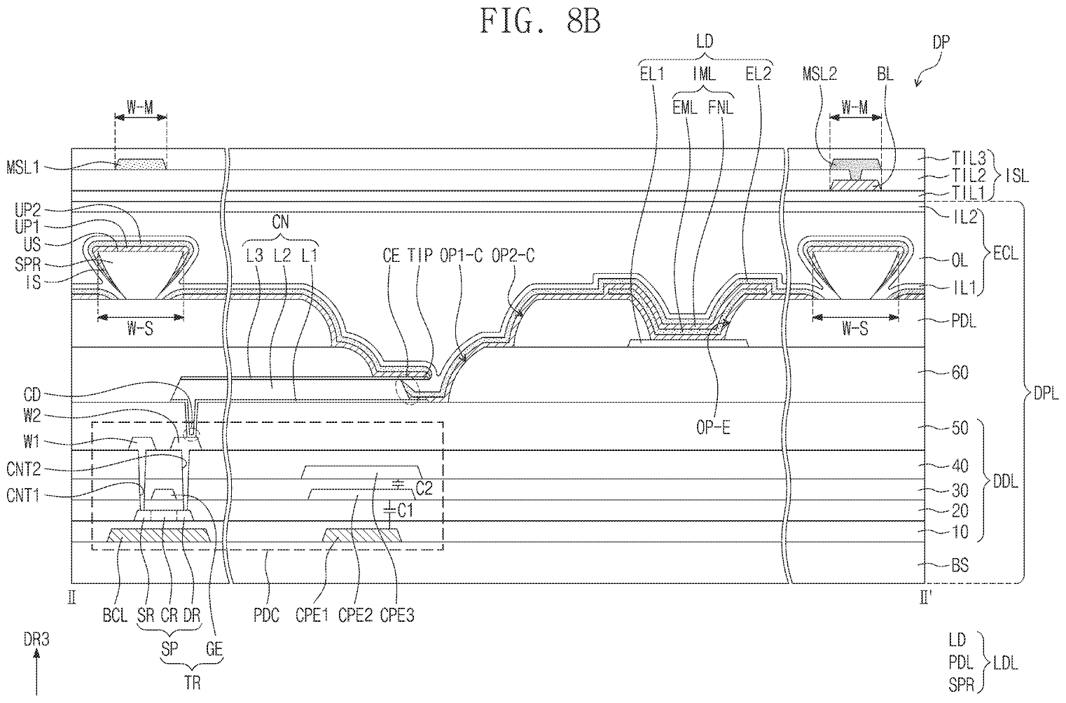

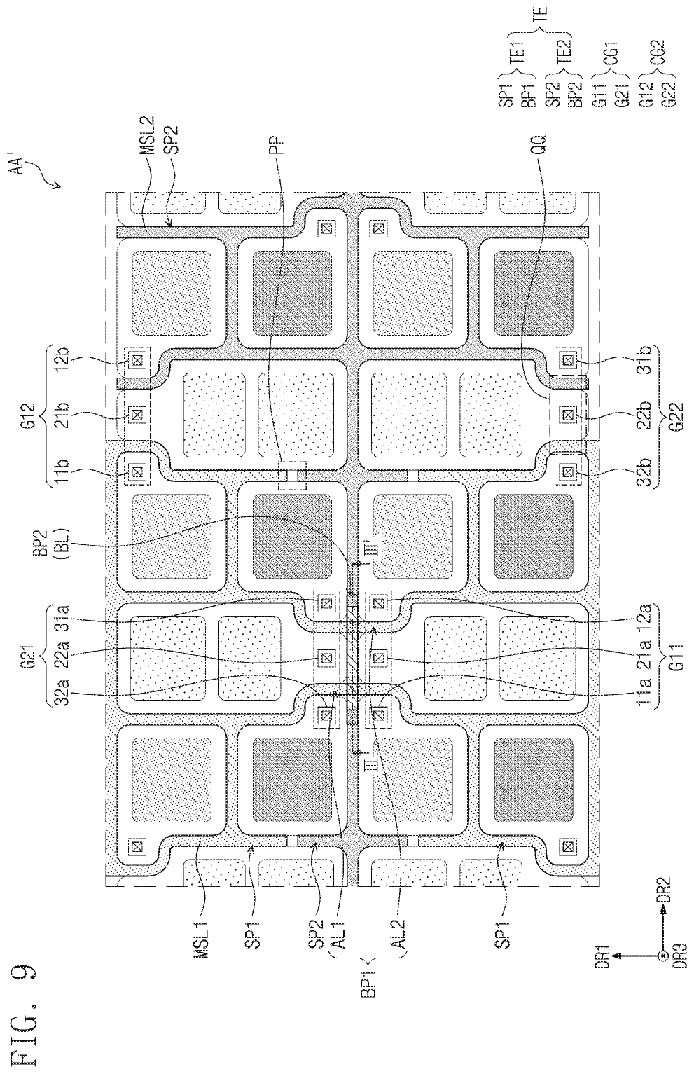

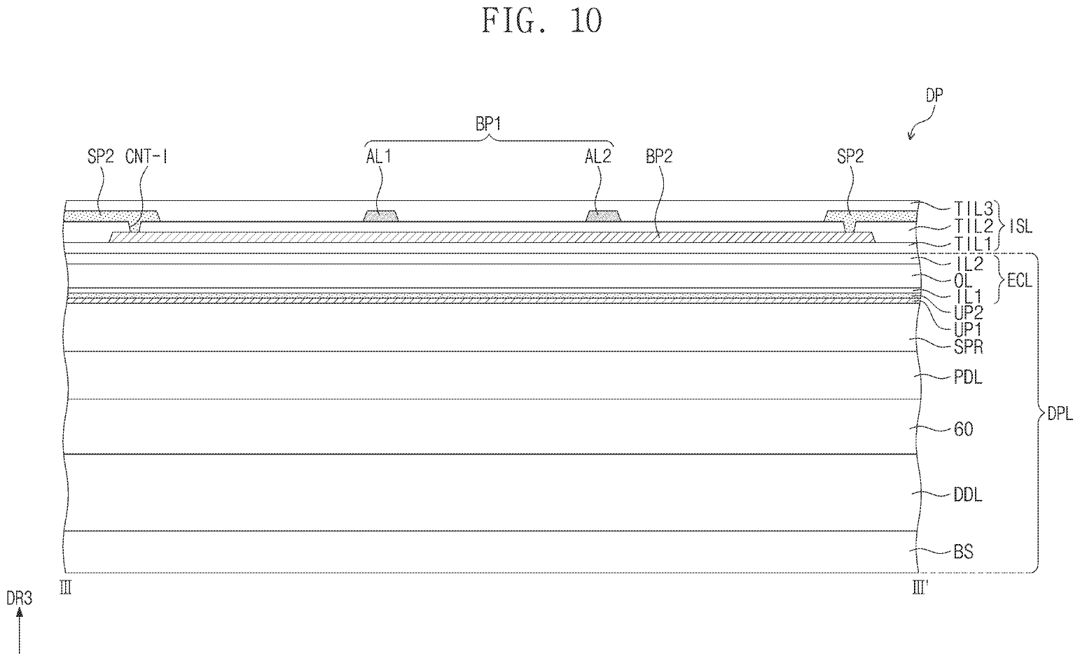

FIG. 7 is an enlarged plan view illustrating some of components of a display panel in a display area according to an embodiment of the inventive concept. FIGS. 8A and 8B are cross-sectional views illustrating a partial region of a display panel, taken along line II-II′ of FIG. 7, according to an embodiment of the inventive concept. FIG. 9 is an enlarged plan view of the region AA′ (for example, the region AA′) of FIG. 7 illustrating some of components of a display panel according to an embodiment of the inventive concept. FIG. 10 is an enlarged cross-sectional view illustrating a partial region of a display panel, taken along line III-III′ of FIG. 9, according to an embodiment of the inventive concept.

FIG. 7 illustrates the emission parts EP, the separator SPR, and the sensing electrodes TE. For convenience, the emission connection parts CE are also illustrated. With regard to descriptions about the emission parts EP, the separator SPR, and the emission connection parts CE, the descriptions provided above with reference to FIGS. 4A to 5B may be similarly applied. FIG. 9 is an enlarged view of a partial region of FIG. 7. Hereinafter, an arrangement relationship between the emission parts EP, the emission connection parts CE, and the sensing electrodes TE will be described with reference to FIGS. 7 to 9.

Referring to FIG. 7, the sensing electrodes TE each may include mesh lines MSL1 and MSL2. In the present embodiment, the sensing electrodes TE may include the first sensing electrode TE1 and the second sensing electrode TE2. A mesh line of each of the first sensing electrodes TE1 may include a first mesh line MSL1. The first mesh line MSL1 may include lines extending in the first direction DR1 and in the second direction DR2. A mesh line of each of the second sensing electrodes TE2 may include a second mesh line MSL2. The second mesh line MSL2 may include lines extending in the first direction DR1 and in the second direction DR2.

In the present embodiment, the first sensing patterns SP1 and the first intermediate patterns BP1 of each of the first sensing electrodes TE1 may be formed in an integrated shape, and the first mesh line MSL1 may constitute the first sensing patterns SP1 and the first intermediate patterns BP1. The second sensing patterns SP2 and the second intermediate patterns BP2 of each of the second sensing electrodes TE2 may be arranged on different layers, and the second mesh line MSL2 may constitute the second sensing patterns SP2 in the second sensing electrodes TE2. The first mesh line MSL1 and the second mesh line MSL2 may be included in the second conductive layer MTL2 (see FIG. 6B).

The first mesh line MSL1 included in one first sensing electrode TE1 may have a mesh shape generally extending in the first direction DR1, and the second mesh line MSL2 included in one second sensing electrode TE2 may have a mesh shape generally extending in the second direction DR2.

In an embodiment of the inventive concept, the mesh lines MSL1 and MSL2 may be arranged overlapping the separator SPR in a plan view. In a plan view, the first mesh line MSL1 may be arranged generally overlapping the separator SPR, and the second mesh line MSL2 may be arranged generally overlapping the separator SPR.

In a plan view, the first mesh line MSL1 and the second mesh line MSL2 may be arranged spaced apart from each other in a region overlapping the separator SPR. Accordingly, in a plan view, the first mesh line MSL1 may be arranged in a portion of the region overlapping the separator SPR, and the second mesh line MSL2 may be arranged in another portion of the region overlapping the separator SPR except for the portion of the region in which the first mesh line MSL1 is arranged. Accordingly, the first mesh line MSL1 may have the same shape as a portion of the separator SPR, and the second mesh line MSL2 may have the same shape as another portion of the separator SPR in a plan view. The first mesh line MSL1 and the second mesh line MSL2 may not overlap the emission parts EP and the emission connection parts CE.

The emission part EP in one light-emitting device LD (see FIG. 5A) and the emission connection part CE connected to the one light-emitting device LD (see FIG. 5A) may be at least partially surrounded by at least a portion of the first mesh line MSL1 and second mesh line MSL2. In detail, the emission part EP in one light-emitting device LD (see FIG. 5A) and the emission connection part CE connected to the one light-emitting device LD (see FIG. 5A), according to an arrangement position, may be entirely surrounded by one of the first mesh line MSL1 and the second mesh line MSL2, or may be partially surrounded by one of the first mesh line MSL1 and the second mesh line MSL2, or a portion of the emission part EP and the emission connection part CE may be surrounded by the first mesh line MSL1 and another portion of the emission part EP and the emission connection part CE may be surrounded by the second mesh line MSL2. Since the separator SPR provides the opening regions OP (see FIG. 4A) including a protruding portion protruding from the emission part EP so as to arrange the emission connection part CE not overlapping the emission part EP, the separator SPR may have a curved shape in a region in which the emission connection part CE is arranged. Accordingly, the first mesh line MSL1 and the second mesh line MSL2 may also have a partially curved shape in a region adjacent to the emission connection part CE.

According to the present embodiment, the display device DD (see FIG. 1) may be provided, which does not affect light provided from the emission parts EP and does not reduce light emission efficiency even when the second conductive layer MTL2 (see FIG. 6B) is arranged on the display layer DPL (see FIG. 5A).

FIG. 7 illustrates, as an example, that the first mesh line MSL1 and the second mesh line MSL2 each have a rounded shape at an intersection portion. However, an embodiment of the inventive concept is not limited thereto, and the first mesh line MSL1 and the second mesh line MSL2 may have perpendicular edges at the intersection portion without a rounded portion.

Referring to FIGS. 7 to 8B, in an embodiment of the inventive concept, a width W-M of each of the first mesh line MSL1 and the second mesh line MSL2 may be equal to or less than a width W-S of the separator SPR in a cross-sectional view. In the present disclosure, the width W-S of the separator SPR may represent a maximum width of the separator SPR. FIGS. 7 and 8A illustrate, as an example, that the width W-M of each of the first mesh line MSL1 and the second mesh line MSL2 is equal to the width W-S of the separator SPR in a cross-sectional view, and FIG. 8B illustrates, as an example, that the width W-M of each of the first mesh line MSL1 and the second mesh line MSL2 is less than the width W-S of the separator SPR in a cross-sectional view.

The second intermediate patterns BP2 may include bridge lines BL. The bridge lines BL may insulatively intersect the first intermediate patterns BP1. The bridge lines BL may also overlap the separator SPR, and a width (see W-M) of each of the bridge lines BL may be equal to or less than the width W-S of the separator SPR in a cross-sectional view. Likewise, FIG. 8A illustrates, as an example, that the width (see W-M) of each of the bridge line BL is equal to the width W-S of the separator SPR in a cross-sectional view, and FIG. 8B illustrates, as an example, that the width (see W-M) of each of the bridge line BL is less than the width W-S of the separator SPR in a cross-sectional view.

Although FIGS. 8A and 8B illustrate, as an example, that the first and second mesh lines MSL1 and MSL2 and the bridge line BL have the same width W-M, an embodiment of the inventive concept is not limited thereto, and the first and second mesh lines MSL1 and MSL2 and the bridge line BL may have different widths.

According to an embodiment of the inventive concept, since the first sensing electrodes TE1 and the second sensing electrodes TE2 are provided so as to overlap the separator SPR and have a width equal to or less than the width of the separator SPR, the first sensing electrodes TE1 and the second sensing electrodes TE2 may not overlap the second electrode EL2 of each of the light-emitting devices LD or may minimize an area overlapping the second electrode EL2. In the present embodiment, the second electrode EL2 may be electrically connected to the connection transistor TR so as to receive a voltage that varies according to an image signal. That is, when a variable voltage is applied to the second electrode EL2 arranged on an upper side of the light-emitting device LD, the sensing electrodes TE1 and TE2 may be affected by the variable voltage and thus may generate or increase noise as a size of an area in which the sensing electrodes TE1 and TE2 overlap the second electrode EL2 increases.

According to an embodiment of the inventive concept, since the first sensing electrodes TE1 and the second sensing electrodes TE2 are arranged so as not to overlap the second electrode EL2 or minimize the area overlapping the second electrode EL2, influence of the variable voltage applied to the second electrode EL2 to the first sensing electrodes TE1 and the second sensing electrodes TE2 may be minimized, and thus noise that occurs in the first sensing electrodes TE1 and the second sensing electrodes TE2 may be eliminated or reduced.

In the present embodiment, as described above, the emission connection parts CE may be arranged adjacent to each other to form the contact groups CG1 and CG2. The contact groups CG1 and CG2 each may include the emission connection parts CE aligned along the second direction DR2 and arranged adjacent to each other.

The contact groups CG1 and CG2 may include first contact group CG1 and second contact groups CG2. The first contact groups CG1 may include 1-1st sub groups G11 and 2-1st sub groups G21, and the second contact groups CG2 may include 1-2nd sub groups G12 and 2-2nd sub groups G22.

FIG. 9 illustrates an enlarged view of a portion in which one 1-1st sub group G11 and one 2-1st sub group G21 of the first contact groups CG1 and one 1-2nd sub group G12 and one 2-2nd sub group G22 of the second contact groups CG2 are arranged. Hereinafter, an arrangement relationship between the first and second contact groups CG1 and CG2 and the first and second mesh lines MSL1 and MSL2 will be described in detail with reference to FIG. 9.

Referring to FIGS. 7 and 9, the first sensing electrodes TE1 and the second sensing electrodes TE2 may insulatively intersect each other at a portion adjacent to the first contact groups CG1.

The first contact group CG1 may include a 1-1st sub group G11 and a 2-1st sub group G21. The 1-1st sub group G11 may include a 1-1st emission connection part 11a, a 2-1st emission connection part 21a, and a 1-2nd emission connection part 12a spaced apart from each other and arranged in the second direction DR2. That is, the 1-1st emission connection part 11a and the 1-2nd emission connection part 12a may be spaced apart in the second direction DR2 with the 2-1st emission connection part 21a disposed therebetween. The 2-1st sub group G21 may include a 3-2nd emission connection part 32a, a 2-2nd emission connection part 22a, and a 3-1st emission connection part 31a spaced apart from each other and arranged in the second direction DR2. That is, the 3-1st emission connection part 31a and the 3-2nd emission connection part 32a may be spaced apart in the second direction DR2 with the 2-2nd emission connection part 22a disposed therebetween.

The 1-1st sub group G11 and the 2-1st sub group G21 adjacent to each other may face each other in the first direction DR1. In detail, the 1-1st, 2-1st, and 1-2nd emission connection parts 11a, 21a, and 12a in the 1-1st sub group G11 may respectively face the 3-2nd, 2-2nd, and 3-1st emission connection parts 32a, 22a, and 31a in the first direction DR1. The 1-1st to 3-2nd emission connection parts 11a, 21a, 31a, 12a, 22a, and 32a in the first contact group CG1 of FIG. 9 May correspond to the 1-1st to 3-2nd emission connection parts CE1a, CE2a, CE3a, CE1b, CE2b, and CE3b described above with reference to FIG. 4B.

The first sensing electrodes TE1 may include the first sensing patterns SP1 and the first intermediate pattern BP1 arranged between adjacent first sensing patterns SP1, and the first intermediate pattern BP1 may have an integrated form with the first sensing patterns SP1. In the present embodiment, the first intermediate pattern BP1 may intersect the first contact group CG1 along the first direction DR1.

The first intermediate pattern BP1 may include a first intermediate line AL1 and a second intermediate line AL2. That is, the first mesh line MSL1 constituting the first intermediate pattern BP1 may be defined as the first intermediate line AL1 and the second intermediate line AL2. The first intermediate line AL1 and the second intermediate line AL2 may extend in the first direction DR1 and may be spaced apart from each other in the second direction DR2.

The first intermediate line AL1 may extend across a portion between the 1-1st emission connection part 11a and the 2-1st emission connection part 21a in the 1-1st sub group G11, and may extend across a portion between the 3-2nd emission connection part 32a and the 2-2nd emission connection part 22a in the 2-1st sub group G21.

The second intermediate line AL2 may extend across a portion between the 1-2nd emission connection part 12a and the 2-1st emission connection part 21a in the 1-1st sub group G11, and may extend across a portion between the 3-1st emission connection part 31a and the 2-2nd emission connection part 22a in the 2-1st sub group G21.

The 2-1st emission connection part 21a in the 1-1st sub group G11 and the 2-2nd emission connection part 22a in the 2-1st sub group G21 may be arranged between the first intermediate line AL1 and the second intermediate line AL2.

Since the first intermediate pattern BP1 is arranged across a portion between adjacent emission connection parts CE, the first sensing electrode TE1 may extend along a region protruding from the 2-1st emission part EP2a (see FIG. 4B) in the first direction DR1 and a region protruding from the 2-2nd emission part EP2b (see FIG. 4B) in an opposite direction to the first direction DR1 in the opening region OP (see FIG. 4A) of the separator SPR. Accordingly, since a size of an area occupied by the first sensing electrode TE1 in a region in which the first sensing electrode TE1 and the second sensing electrode TE2 intersect may be reduced, an area in which the second sensing pattern SP2 which includes the same layer as the first sensing electrode TE1 is arranged may be increased.

The second sensing electrodes TE2 may include the second sensing patterns SP2 and the second intermediate pattern BP2 arranged between the second sensing patterns SP2, and the second intermediate pattern BP2 may be arranged on a layer different from that of the second sensing patterns SP2.

In an embodiment, the second intermediate pattern BP2 may be arranged adjacent to the first contact group CG1. For example, the second intermediate pattern BP2 may be arranged between the 1-1st sub group G11 and the 2-1st sub group G21.

That is, the second intermediate pattern BP2 may include the bridge line BL extending along a portion between the 1-1st sub group G11 and the 2-1st sub group G21 in the second direction DR2. The bridge line BL may intersect the first intermediate line AL1 and the second intermediate line AL2 in a plan view, but the second intermediate pattern BP2 is arranged on a layer different from that of the first intermediate pattern BP1, and thus may be arranged so as to insulatively intersect the first intermediate line AL1 and the second intermediate line AL2.

Meanwhile, FIGS. 7 and 9 illustrate, as an example, a shape and arrangement of the second intermediate pattern BP2 in a plan view, but the second intermediate pattern BP2 may extend in various shapes along an extension direction of the separator SPR provided that the second intermediate pattern BP2 is connected to adjacent second sensing patterns SP2 so as to connect the adjacent second sensing patterns SP2.

Referring to FIG. 10, the second intermediate pattern BP2 may be arranged on the first sensing insulating layer TIL1 and covered by the second sensing insulating layer TIL2, and the first intermediate pattern BP1 may be arranged on the second sensing insulating layer TIL2 and covered by the third sensing insulating layer TIL3. Accordingly, the first intermediate pattern BP1 and the second intermediate pattern BP2 may be insulated by the second sensing insulating layer TIL2 and intersect each other. The second intermediate pattern BP2 may be electrically connected to the second sensing patterns SP2 through a contact hole CNT-I formed in the second sensing insulating layer TIL2.

Meanwhile, according to another embodiment of the inventive concept, the second intermediate pattern BP2 may be arranged on the second sensing insulating layer TIL2 and covered by the third sensing insulating layer TIL3, and the first sensing patterns SP1, the first intermediate pattern BP1, and the second sensing patterns SP2 may be arranged on the first sensing insulating layer TIL1 and covered by the second sensing insulating layer TIL2. That is, the second intermediate pattern BP2 may be included in the second conductive layer MTL2 (see FIG. 6B), and the first sensing patterns SP1, the first intermediate pattern BP1, and the second sensing patterns SP2 may be included in the first conductive layer MTL1 (see FIG. 6B).

Referring back to FIGS. 7 and 9, in the present embodiment, only one mesh line among the first mesh line MSL1 and the second mesh line MSL2 may be arranged between adjacent emission parts among the emission parts EP (or between adjacent second electrodes among the second electrodes EL2_1, EL2_2, and EL2_3 (see FIG. 4B)) in a plan view. Accordingly, a portion of the one emission part EP may be surrounded by the first mesh line MSL1, and another portion of the one emission part EP may be surrounded by the second mesh line MSL2. The first and second mesh lines MSL1 and MSL2 adjacent to each other may include portions facing each other with one emission part EP disposed therebetween.

Furthermore, in a plan view, the first mesh line MSL1 and the second mesh line MSL2 may include a portion PP at which the first mesh line MSL1 and the second mesh line MSL2 are spaced apart from each other and facing each other in an area between adjacent emission parts EP (or between adjacent second electrodes EL2_1, EL2_2, and EL2_3 (see FIG. 4B)). The first mesh line MSL1 and the second mesh line MSL2 may be disconnected between the adjacent emission parts EP, and disconnected portions of the first mesh line MSL1 and the second mesh line MSL2 may face each other. For example, the first and second mesh lines MSL1 and MSL2 may extend in the first direction DR1 between the adjacent emission parts EP and face each other in the first direction DR1 that is an extension direction.

Furthermore, according to an embodiment of the inventive concept, the first mesh line MSL1 and the second mesh line MSL2 may include a portion QQ at which the first mesh line MSL1 and the second mesh line MSL2 intersect the second contact groups CG2 and are spaced apart and facing each other.

The second contact group CG2 may include a 1-2nd sub group G12 and a 2-2nd sub group G22. The 1-2nd sub group G12 may include a 1-1st emission connection part 11b, a 2-1st emission connection part 21b, and a 1-2nd emission connection part 12b arranged in the second direction DR2. The 2-2nd sub group G22 may include a 3-2nd emission connection part 32b, a 2-2nd emission connection part 22b, and a 3-1st emission connection part 31b arranged in the second direction DR2. The 1-1st to 3-2nd emission connection parts 11b, 21b, 31b, 12b, 22b, and 32b in the second contact group CG2 of FIG. 9 May correspond to the 1-1st to 3-2nd emission connection parts CE1a, CE2a, CE3a, CE1b, CE2b, and CE3b described above with reference to FIG. 4B. That is, in the present embodiment, a portion of the contact groups CG described above with reference to FIG. 4B may correspond to the first contact group CG1 of FIG. 9 and another portion may correspond to the second contact group CG2 according a position of the contact groups CG.

In the present embodiment, an outer periphery portion of the first mesh line MSL1 forming an outer periphery of each of the first sensing patterns SP1 may surround a portion of the emission connection parts CE included in the second contact group CG2.

For example, the outer periphery portion of the first mesh line MSL1 may include a portion surrounding the 1-1st emission connection part 11b in the 1-2nd sub group G12 and the 3-2nd emission connection part 32b in the 2-2nd sub group G22, and this portion may correspond to a portion forming an outermost periphery in the second direction DR2. FIG. 9 illustrates an enlarged view of only one side of one first sensing pattern SP1, and, as illustrated in FIG. 7, on the other side opposed in the second direction DR2, a portion of each of the 1-2nd emission connection part 12b in the 1-2nd sub group G12 and the 3-1st emission connection part 31b in the 2-2nd sub group G22 may be surrounded.

In the present embodiment, an outer periphery portion of the second mesh line MSL2 forming an outer periphery of each of the second sensing patterns SP2 may surround another portion of the emission connection parts CE included in the second contact group CG2.

For example, the outer periphery portion of the second mesh line MSL2 may include a portion surrounding a portion of each of the 1-2nd emission connection part 12b in the 1-2nd sub group G12 and the 3-1st emission connection part 31b in the 2-2nd sub group G22, and this portion may correspond to portions forming an outermost periphery in the second direction DR2. FIG. 9 illustrates an enlarged view of one side of one second sensing pattern SP2, and, as illustrated in FIG. 7, on the other side opposed in the second direction DR2, a portion of each of the 1-1st emission connection part 11b in the 1-2nd sub group G12 and the 3-2nd emission connection part 32b in the 2-2nd sub group G22 may be surrounded.

Accordingly, according to the present embodiment, the first mesh line MSL1 and the second mesh line MSL2 may face each other in the second direction DR2 with the 2-1st emission connection part 21b or the 2-2nd emission connection part 22b disposed therebetween in a region adjacent to the second contact group CG2. That is, in the region adjacent to the second contact group CG2, a gap portion or boundary portion between the first mesh line MSL1 and the second mesh line MSL2 may be formed.

In the six adjacent emission connection parts CE in the second contact group CG2, an electric field may relatively significantly change since voltages that have different values and vary in real time are applied to the second electrodes EL2 (see FIG. 8A). According to the present embodiment, since the gap portion or boundary portion between the first mesh line MSL1 and the second mesh line MSL2 is provided in the second contact group CG2, outer periphery portions of the first sensing electrode TE1 and the second sensing electrode TE2 are arranged in the second contact group CG2, thus minimizing influence on sensing sensitivity change. Therefore, according to the present embodiment, since the sensing electrodes TE1 and TE2 that reduce noise with the display layer DPL (see FIG. 8A) may be provided, the display layer DPL (see FIG. 8A) with reduced image sticking defect and improved lifespan may be provided, and the display device DD (see FIG. 1) with improved sensing sensitivity may also be provided.

Meanwhile, a shape and arrangement of the first mesh line MSL1 and the second mesh line MSL2 illustrated in FIGS. 7 and 9 are not limited to a certain embodiment, and may be variously modified provided that the first sensing electrodes TE1 and the second sensing electrodes TE2 are provided so as to be spaced apart from each other and arranged intersecting each other and overlapping the separator SPR.

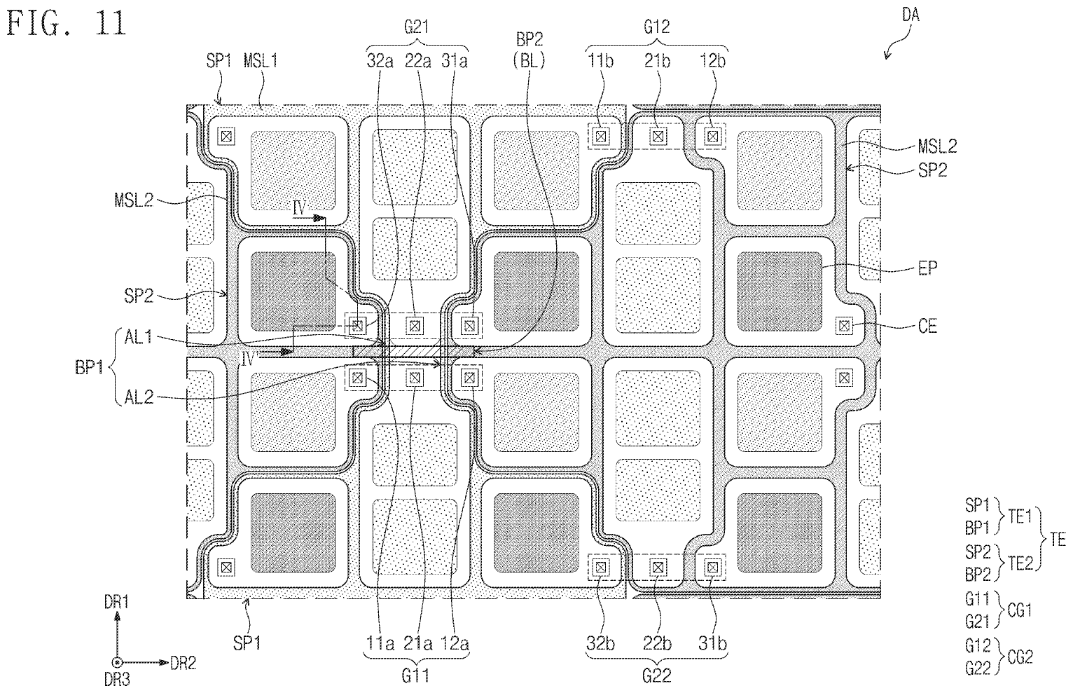

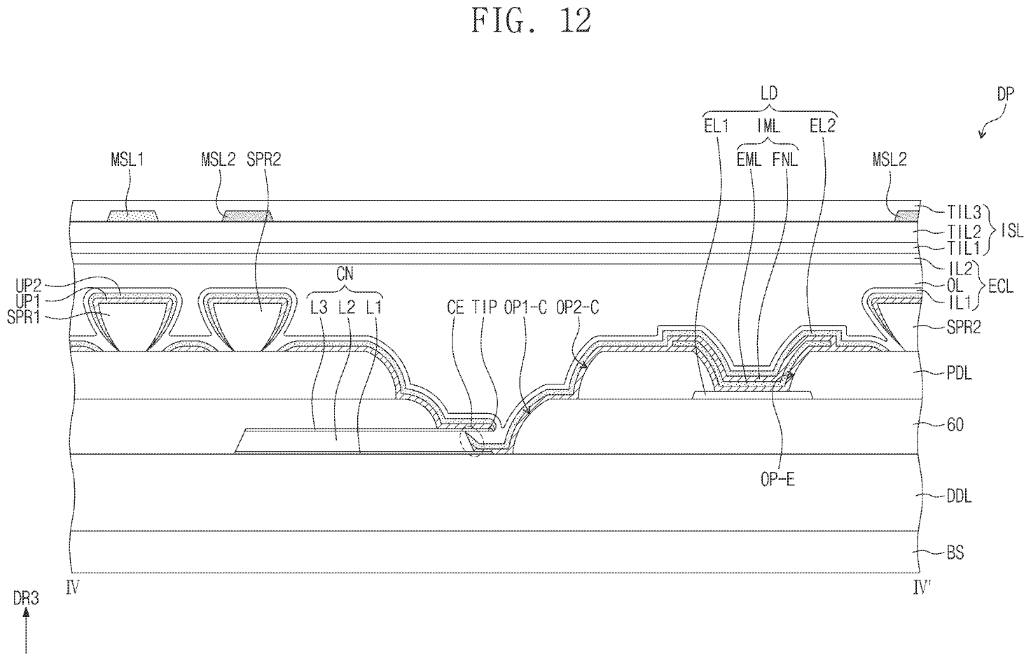

FIG. 11 is an enlarged plan view illustrating some of components of a display panel in a display area according to an embodiment of the inventive concept. FIG. 12 is an enlarged cross-sectional view illustrating a partial region of a display panel, taken along line IV-IV′ of FIG. 11 according to an embodiment of the inventive concept.

FIG. 11 illustrates the emission parts EP, the separator SPR (see FIG. 7), and the sensing electrodes TE. For convenience, the emission connection parts CE are also illustrated. Hereinafter, an arrangement relationship between the emission parts EP, the emission connection parts CE, and the sensing electrodes TE in a plan view will be described with reference to FIGS. 11 and 12.

Referring to FIGS. 11 and 12, in the present embodiment, a plurality of mesh lines MSL1 and MSL2 may be arranged between adjacent emission parts among the emission parts EP (or between adjacent second electrodes among the second electrodes EL2_1, EL2_2, and EL2_3 (see FIG. 4B)). The first mesh line MSL1 and the second mesh line MSL2 both may be arranged between the adjacent emission parts EP (or between adjacent second electrodes EL2_1, EL2_2, and EL2_3 (see FIG. 4B)).

In the present embodiment, the emission parts EP each may be entirely surrounded by either the first mesh line MSL1 or the second mesh line MSL2. Accordingly, the first mesh line MSL1 and the second mesh line MSL2 adjacent to each other may directly face each other between adjacent emission parts EP. For example, an outer periphery portion of the first mesh line MSL1 forming an outer periphery of the first sensing electrode TE1 may all directly face an outer periphery portion of the second mesh line MSL2 forming an outer periphery of the second sensing pattern SP2. Furthermore, a portion in which the first mesh line MSL1 and the second mesh line MSL2 are disconnected and disconnected portions face each other may not be included between adjacent emission parts EP.

In an embodiment, the first mesh line MSL1 and the second mesh line MSL2 facing each other between the adjacent emission parts EP may be respectively arranged on separated separators SPR1 and SPR2. That is, the separators SPR1 and SPR2 may include a first separator SPR1 overlapping the first mesh line MSL1 and a second separator SPR2 overlapping the second mesh line MSL2, and the first separator SPR1 and the second separator SPR2 may be separated from each other. In a plan view, a shape of the first mesh line MSL1 may be the same as at least a portion of the first separator SPR1, and a shape of the second mesh line MSL2 may be the same as at least a portion of the second separator SPR2.

Since the first separator SPR1 overlapping the first mesh line MSL1 and the second separator SPR2 overlapping the second mesh line MSL2 are separately provided, coupling noise with the second dummy pattern layer UP2 including the same material as the second electrode EL2 may be reduced in a portion in which the first and second mesh lines MSL1 and MSL2 face each other.

The emission connection parts CE may be arranged adjacent to each other to form the contact groups CG1 and CG2. In the present embodiment, the contact groups CG1 and CG2 may include first contact group CG1 and second contact groups CG2. The first contact groups CG1 may include a 1-1st sub group G11 and a 2-1st sub group G21, and the second contact groups CG2 may include a 1-2nd sub group G12 and a 2-2nd sub group G22. The descriptions of the 1-1st sub group G11, 2-1st sub group G21, 1-2nd sub group G12, and 2-2nd sub group G22 provided above with reference to FIG. 9 May be similarly applied to FIG. 11.

Compared to the embodiment described above with reference to FIG. 9, the second mesh line MSL2 according to the present embodiment may extend along an outer periphery of the first sensing electrode TE1 so as to further surround each of the 3-1st emission connection part 31a, 3-2nd emission connection part 32a, 1-1st emission connection part 11a, and 1-2nd emission connection part 12a in the first contact group CG1. Accordingly, each of the first intermediate line AL1 and second intermediate line AL2 and the second mesh line MSL2 may face each other in a direction intersecting an extension direction between adjacent emission connection parts CE in the first contact group CG1.

Compared to the embodiment described above with reference to FIG. 9, the second mesh line MSL2 according to the present embodiment may extend along an outer periphery of the first sensing electrode TE1 so as to further surround each of the 2-1st emission connection part 21b and the 2-2nd emission connection part 22b in the second contact group CG2. Accordingly, the first mesh line MSL1 and the second mesh line MSL2 may face each other in a direction intersecting an extension direction in an area between adjacent emission connection parts CE in the second contact group CG2.

Accordingly, the first sensing electrode TE1 and the second sensing electrode TE2 may form a boundary within a relatively short distance, and, for example, a sensing region of the second sensing electrode TE2 may extend closer to a sensing region of the first sensing electrode TE1. Therefore, sensing sensitivity may be improved at a boundary portion between the first sensing electrode TE1 and the second sensing electrode TE2.

Furthermore, according to the present embodiment, two ends of the second sensing electrode TE2 in the first direction DR1 may be formed of the second mesh line MSL2 extending in the second direction DR2. In the embodiment described above with reference to FIG. 7, the second sensing electrodes TE2 include disconnected ends, and thus the second mesh lines MSL2 of adjacent second sensing electrodes TE2 face each other in an extension direction, whereas, in the present embodiment, the second mesh lines MSL2 forming the ends of adjacent second sensing electrodes TE2 may be arranged facing each other in a direction intersecting the extension direction. Accordingly, since adjacent second sensing electrodes TE2 also form a boundary within a relatively short distance, sensing regions of the second sensing electrodes TE2 may extend closer to each other, and sensing sensitivity may be improved at the boundary portion between the adjacent second sensing electrodes TE2.

Therefore, according to the present embodiment, since a region that may be sensed by the first sensing electrodes TE1 and the second sensing electrodes TE2 is increased, the display device DD (see FIG. 1) with further improved sensing sensitivity may be provided.

Meanwhile, FIG. 11 illustrates that the first mesh line MSL1 forming an inner side of the first sensing pattern SP1 and the first mesh line MSL1 forming an outer periphery of the first sensing pattern SP1 have different widths, and the second mesh line MSL2 forming an inner side of the second sensing pattern SP2 and the second mesh line MSL2 forming an outer periphery of the second sensing pattern SP2 have different widths, but an embodiment of the inventive concept is not limited thereto, and the first mesh line MSL1 and the second mesh line MSL2 may have generally the same width.

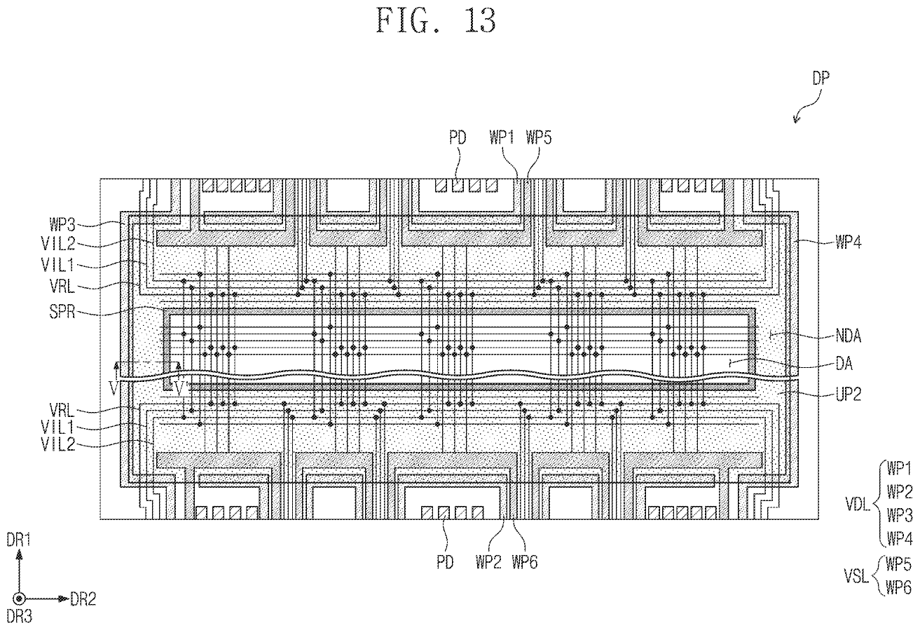

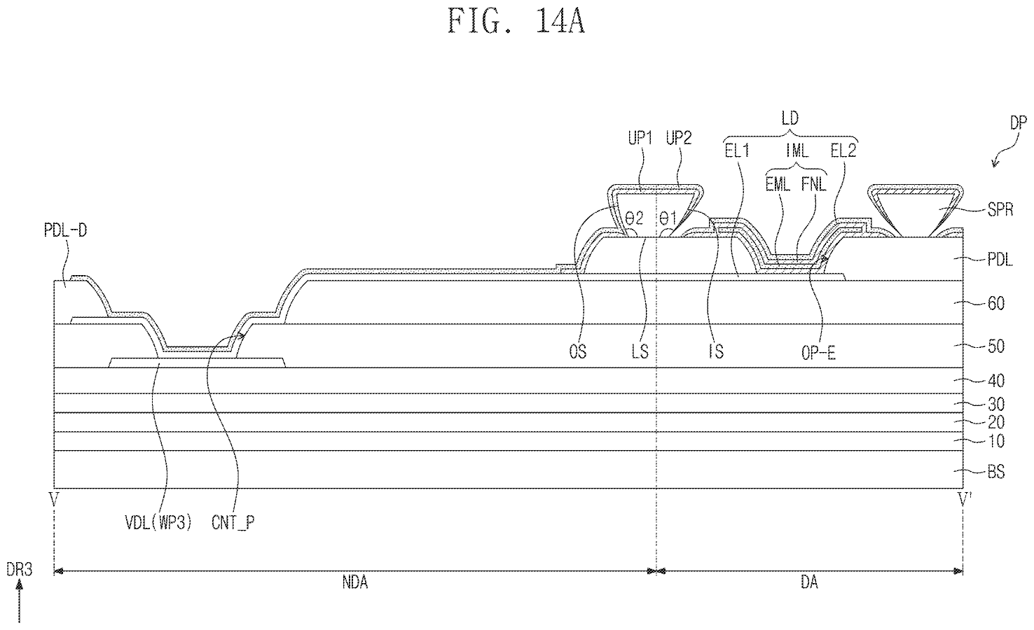

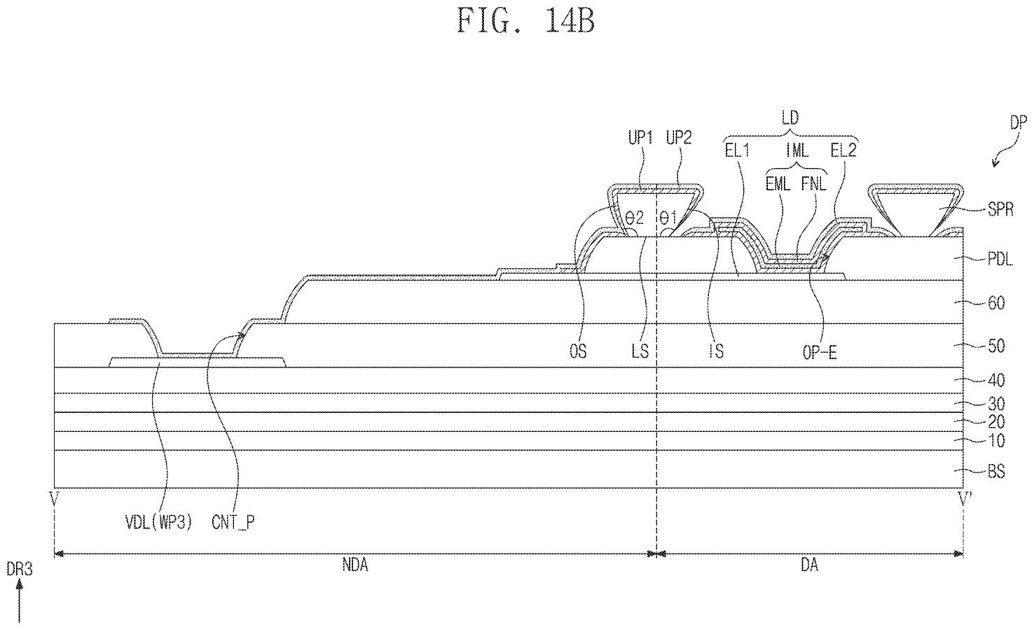

FIG. 13 is a plan view illustrating some of components of a display panel according to an embodiment of the inventive concept. FIGS. 14A and 14B are enlarged cross-sectional views illustrating a partial region of a display panel, taken along line V-V′ of FIG. 13, according to an embodiment of the inventive concept.

FIG. 13 is a plan view illustrating some of components of a display panel according to an embodiment of the inventive concept. FIG. 13 illustrates an enlarged view of portions of the plurality of power supply lines VDL, VSL, VIL1, VIL2, and VRL, the separator SPR, and the second dummy pattern layer UP2.

Referring to FIG. 13, the plurality of power supply lines VDL, VSL, VIL1, VIL2, and VRL to which various constant voltages required for the display panel DP are provided may pass via the peripheral area NDA. The plurality of power supply lines VDL, VSL, VIL1, VIL2, and VRL may have a mesh structure in the display area DA in order to provide volage to the pixels PXij (see FIG. 1) arranged in the display panel DP.

The plurality of power supply lines VDL, VSL, VIL1, VIL2, and VRL may include the first power supply line VDL, the second power supply line VSL, the first initialization voltage line VIL1, the second initialization voltage line VIL2, and the reference voltage line VRL.

In the present embodiment, the first power supply line VDL may include a first wiring part WP1, a second wiring part WP2, a third wiring part WP3, and a fourth wiring part WP4.

The first wiring part WP1 may be arranged spaced apart from the display area DA in the first direction DR1, and the second wiring part WP2 may be arranged spaced apart from the display area DA in an opposite direction to the first direction DR1. The first wiring part WP1 and the second wiring part WP2 each may include a plurality of patterns arranged in the second direction DR2.

The third wiring part WP3 may be arranged spaced apart from the display area DA in an opposite direction to the second direction DR2, and the fourth wiring part WP4 may be arranged spaced apart from the display area DA in the second direction DR2. The third wiring part WP3 and the fourth wiring part WP4 each may include a portion extending in the first direction DR1.

In the present embodiment, the second power supply line VSL may include a fifth wiring part WP5 and a sixth wiring part WP6.

The fifth wiring part WP5 may be arranged spaced apart from the display area DA in the first direction DR1, and the sixth wiring part WP6 may be arranged spaced apart from the display area DA in an opposite direction to the first direction DR1. The fifth wiring part WP5 and the sixth wiring part WP6 each may include a plurality of patterns arranged in the second direction DR2.

The first initialization voltage line VIL1, the second initialization voltage line VIL2, and the reference voltage line VRL each may include lines arranged between the display area DA and the first and second power supply lines VDL and VSL and extending in the second direction DR2.

However, arrangement of the first power supply line VDL, the second power supply line VSL, the first initialization voltage line VIL1, the second initialization voltage line VIL2, and the reference voltage line VRL is not limited thereto, and may be variously modified according to design of other lines in the peripheral area NDA and a shape/arrangement of the display area DA and peripheral area NDA.

The pads PD may be arranged adjacent to an end of the peripheral area NDA in the first direction DR1. In the present embodiment, one portion of the pads PD may be arranged adjacent to an upper end of the peripheral area NDA, and the other portion of the pads PD may be arranged adjacent to a lower end of the peripheral area NDA. However, arrangement of the pads PD is not limited thereto, and the pads PD may be only arranged adjacent to one-side end of the peripheral area NDA.

FIG. 13 schematically illustrates a portion forming an outer periphery of the separator SPR. A portion of the separator SPR which forms the outer periphery illustrated in FIG. 13 May be a portion overlapping the peripheral area NDA, and may correspond to a remaining portion excluding a portion included in the light-emitting unit described above with reference to FIG. 4A. In an embodiment, the outer periphery of the separator SPR may have a quadrilateral shape.

FIG. 13 schematically illustrates a portion of the second dummy pattern layer UP2 arranged in the peripheral area NDA. According to an embodiment of the inventive concept, the second dummy pattern layer UP2 may be electrically connected to either the first power supply line VDL or the second power supply line VSL. Therefore, the second dummy pattern layer UP2 may receive the first power supply voltage VDD (see FIG. 1) from the first power supply line VDL or receive the second power supply voltage VSS (see FIG. 1) from the second power supply line VSL. Here, the second dummy pattern layer UP2 may be referred to as a dummy conductive pattern.

In an embodiment, the second dummy pattern layer UP2 arranged in the peripheral area NDA may extend from an outer periphery of the separator SPR to the first power supply line VDL in a plan view. Here, the second dummy pattern layer UP2 may be electrically connected to the first power supply line VDL. However, an embodiment of the inventive concept is not limited thereto, and the second dummy pattern layer UP2 may extend up to the second power supply line VSL, and, in this case, the second dummy pattern layer UP2 may be electrically connected to the second power supply line VSL.

FIGS. 14A and 14B are cross-sectional views illustrating a boundary portion between the display area DA and the peripheral area NDA.

Referring to FIG. 14A, the first power supply line VDL may be arranged on the fourth insulating layer 40. The first power supply line VDL may not be covered by the fifth insulating layer 50 and the sixth insulating layer 60 and may be at least partially exposed from the fifth insulating layer 50 by a contact hole CNT_P defined in the fifth insulating layer 50 during a manufacturing process. However, an embodiment of the inventive concept is not limited thereto, and the first power supply line VDL may be arranged on the fifth insulating layer 50. Alternatively, the first power supply line VDL may include both a line arranged on the fourth insulating layer 40 and a line arranged on the fifth insulating layer 50, and the two lines may be electrically connected through a contact hole formed in the fifth insulating layer 50.

In a cross-sectional view seen from the second direction DR2 (see FIG. 13), the first electrode EL1 may extend from the display area DA to the first power supply line VDL (e.g., third wiring part WP3), and may be connected to the first power supply line VDL through the contact hole CNT_P.

The display panel DP may further include a dummy insulating layer PDL-D. The dummy insulating layer PDL-D may cover an end portion of the first electrode EL1 connected to the first power supply line VDL.

An internal angle θ2 formed by an outer surface OS and lower surface LS of the separator SPR may be different from the internal angle θ1 formed by the inner surface IS and lower surface LS of the separator SPR. The internal angle θ2 formed by the outer surface OS and lower surface LS may be less than the internal angle θ1 formed by the inner surface IS and lower surface LS. In an embodiment, the internal angle θ2 formed by the outer surface OS and lower surface LS of the separator SPR may be 95 degrees or less.

Therefore, an end of the first dummy pattern layer UP1 arranged on the inner surface IS of the separator SPR is electrically disconnected from the adjacent intermediate layer IML, but the first dummy pattern layer UP1 arranged on the outer surface OS of the separator SPR may not be disconnected and extend to the outside of the separator SPR along the outer surface OS.

The second dummy pattern layer UP2 may also be formed similarly to the first dummy pattern layer UP1. That is, an end of the second dummy pattern layer UP2 arranged on the inner surface IS of the separator SPR is electrically disconnected from the adjacent second electrode EL2, but the second dummy pattern layer UP2 arranged on the outer surface OS of the separator SPR may not be disconnected and extend to the outside of the separator SPR along the outer surface OS. The second dummy pattern layer UP2 may contact the first electrode EL1 in the peripheral area NDA. The second dummy pattern layer UP2 may receive the first power voltage VDD (see FIG. 1) through the first electrode EL1 connected to the first power supply line VDL.

Referring to FIG. 14B, the second dummy pattern layer UP2 according to the present embodiment may extend from the outer surface OS to the first power supply line VDL and may contact the first power supply line VDL through the contact hole CNT_P so as to be connected to the first power supply line VDL. In this manner, the second dummy pattern layer UP2 may receive the first power supply voltage VDD (see FIG. 1).

According to the present embodiment, a constant voltage may be applied to the second dummy pattern layer UP2 so that the second dummy pattern layer UP2 may not be provided in a floating state on the separator SPR. In this manner, electrical interference of the second dummy pattern layer UP2 which reaches the light-emitting device LD is minimized, thus reducing driving current error of the light-emitting device LD. Since electrical reliability of the light-emitting device LD is improved, the display panel DP with reduced image quality deterioration may be provided. Furthermore, electrical inference of the second dummy pattern layer UP2 which reaches the sensing layer ISL (see FIG. 5A) is also minimized, and thus the display panel DP with improved sensing reliability may be provided.

Meanwhile, FIGS. 13 to 14B illustrate, as an example, that the second dummy pattern layer UP2 is electrically connected to the first power supply line VDL. However, the second dummy pattern layer UP2 may be electrically connected to the second power supply line VSL or may be electrically connected to any one of the first initialization voltage line VIL1, the second initialization voltage line VIL2, and the reference voltage line VRL. That is, provided that the second dummy pattern layer UP2 receives a constant voltage, the type of a voltage line connected to the second dummy pattern layer UP2 is not limited to a certain embodiment.

According to an embodiment of the inventive concept, a display layer with reduced image sticking defect and improved lifespan and a sensing layer having improved sensing sensitivity may be simultaneously provided.

According to an embodiment of the inventive concept, since sensing electrodes are arranged so as not to overlap an electrode of a light-emitting device connected to a transistor or minimize a portion overlapping the electrode of the light-emitting device, influence of a variable voltage applied to the electrode of the light-emitting device may be minimized.

A display layer according to an embodiment of the inventive concept includes a connection line connecting a transistor and an electrode of a light-emitting device, and the connection line includes a driver connection part connected to the transistor and an emission connection part connected to the electrode of the light-emitting device and spaced apart from the driver connection part in a plan view. According to an embodiment of the inventive concept, since a boundary region between first sensing electrodes and second sensing electrodes that are arranged intersecting each other is arranged adjacent to an emission connection part, influence of electric field change may be minimized in the emission connection part.

Therefore, according to an embodiment of the inventive concept, a sensing layer having improved sensing sensitivity may be provided since sensing electrodes having reduced noise with a display layer are included.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A display device comprising:
a separator including a first opening;
a first light-emitting device disposed in the first opening and including a first electrode and a second electrode disposed on the first electrode; and
a sensing electrode arranged on the separator to overlap the separator in a plan view,
wherein a width of the sensing electrode is equal to or less than a width of the separator.

2. The display device of claim 1, wherein the separator further includes a second opening,
wherein the display device further includes a second light emitting device disposed in the second opening and including a first electrode and a second electrode disposed on the first electrode,
wherein the sensing electrode includes:
a first sensing electrode extending in a first direction; and
a second sensing electrode extending in a second direction different from the first direction and insulatively intersecting the first sensing electrode,
wherein the first sensing electrode includes a first mesh line extending in the first direction and the second direction and the second sensing electrode includes a second mesh line extending in the first direction and the second direction.

3. The display device of claim 2, wherein, in a plan view, the first mesh line has the same shape as a portion of the separator corresponding thereto and the second mesh line has the same shape as a portion of the separator corresponding thereto.

4. The display device of claim 2, further comprising transistors electrically connected to each of the second electrode of the first light-emitting device and the second electrode of the second light-emitting device.

5. The display device of claim 4, further comprising:
a first connection line including a first driver connection part connected to a transistor electrically connected to the first light-emitting device and a first emission connection part spaced apart from the first driver connection part in a plan view and connected to the second electrode of the first light-emitting device; and
a second connection line including a second driver connection part connected to a transistor electrically connected to the second light-emitting device and a second emission connection part spaced apart from the second driver connection part in a plan view and connected to the second electrode of the second light-emitting device.

6. The display device of claim 5,
wherein the first light-emitting device includes a first emission part configured to emit first-color light,
wherein the first emission connection part is spaced apart from the first emission part in a plan view, and
wherein the first emission part and the first emission connection part are at least partially surrounded by at least one of the first mesh line or the second mesh line.

7. The display device of claim 5, wherein the first mesh line and the second mesh line have a curved shape at a portion adjacent to the first emission connection part and the second emission connection part.

8. The display device of claim 7, wherein the first mesh line and the second mesh line include portions facing each other with one of the first emission connection part and the second emission connection part disposed therebetween.

9. The display device of claim 7, wherein the first mesh line and the second mesh line include portions facing each other between the first emission connection part and the second emission connection part.

10. The display device of claim 5,
wherein the first sensing electrode includes first sensing patterns arranged in the first direction and first intermediate patterns arranged between the first sensing patterns,
wherein the second sensing electrode includes second sensing patterns arranged in the second direction and second intermediate patterns arranged between the second sensing patterns,
wherein the first sensing patterns, the first intermediate patterns, and the second sensing patterns are arranged on the same layer, and the second intermediate patterns are arranged on a different layer from the layer on which the second sensing patterns are disposed.

11. The display device of claim 10, wherein the first sensing patterns and the first intermediate patterns constitute the first mesh line and the second sensing patterns constitute the second mesh line.

12. The display device of claim 11, wherein an outer periphery portion of the first mesh line constituting an outer periphery of each of the first sensing patterns surrounds a portion of the first emission connection part or a portion of the second emission connection part.

13. The display device of claim 10, further comprising
a first insulating layer, a second insulating layer, and a third insulating layer sequentially laminated on the separator,
wherein the first sensing patterns, the first intermediate patterns, and the second sensing patterns are arranged on the second insulating layer and covered by the third insulating layer,
wherein the second intermediate patterns are arranged on the first insulating layer and covered by the second insulating layer, and
wherein the second sensing patterns and the second intermediate patterns are connected through a contact hole formed in the second insulating layer.

14. The display device of claim 2, further comprising a 1-1st connection line, a 1-2nd connection line, and a 2-1st connection line,
wherein the first light-emitting device includes a 1-1st light-emitting device and a 1-2nd light-emitting device arranged spaced apart from each other with the second light-emitting device disposed therebetween,
wherein the 1-1st connection line includes a 1-1st emission connection part connected to the 1-1st light-emitting device, the 1-2nd connection line includes a 1-2nd emission connection part connected to the 1-2nd light-emitting device, and the 2-1st connection line includes a 2-1st emission connection part connected to the second light-emitting device, and
wherein the 1-1st emission connection part and the 1-2nd emission connection part are spaced apart from each other in the second direction with the 2-1st emission connection part disposed therebetween.

15. The display device of claim 14,
wherein the 1-1st light-emitting device includes a 1-1st emission part that provides first-color light, the 1-2nd light-emitting device includes a 1-2nd emission part that provides the first-color light, and the second light-emitting device includes a 2-1st emission part that provides second-color light having a different color from the first-color light,
wherein the 1-1st emission part and the 1-2nd emission part are spaced apart in the second direction with the 2-1st emission part disposed therebetween, and
wherein the 1-1st emission connection part is spaced apart from the 1-1st emission part in the second direction and the 1-2nd emission connection part is spaced apart from the 1-2nd emission part in an opposite direction to the second direction.

16. The display device of claim 14, wherein a portion of the first mesh line is arranged between the 1-1st emission connection part and the 2-1st emission connection part, and a portion of the second mesh line is arranged between the 1-2nd emission connection part and the 2-1st emission connection part.

17. The display device of claim 14, wherein a portion of the first mesh line and a portion of the second mesh line are arranged spaced apart from each other between the 1-1st emission connection part and the 2-1st emission connection part.

18. The display device of claim 14,
wherein the first sensing electrode includes first sensing patterns arranged in the first direction and first intermediate patterns arranged between the first sensing patterns, and
wherein the first intermediate patterns include a first intermediate line extending in the first direction and a second intermediate line extending in the first direction and facing the first intermediate line in the second direction.

19. The display device of claim 18, wherein the first intermediate line intersects a portion between the 1-1st emission connection part and the 2-1st emission connection part, and the second intermediate line intersects a portion between the 1-2nd emission connection part and the 2-1st emission connection part.

20. The display device of claim 18,
wherein the second sensing electrode includes second sensing patterns arranged in the second direction and second intermediate patterns arranged between the second sensing patterns, and
each of the second intermediate patterns includes a bridge line extending in the second direction and insulatively intersecting the first intermediate line and the second intermediate line.

21. The display device of claim 14, further comprising:
a 3-1st light-emitting device spaced apart from the 1-2nd light-emitting device in the first direction;
a fourth light-emitting device spaced apart from the second light-emitting device in the first direction;
a 3-2nd light-emitting device spaced apart from the 1-1st light-emitting device in the first direction and spaced apart from the 3-1st light-emitting device in the second direction with the fourth light-emitting device disposed therebetween;
a 3-1st connection line including a 3-1st emission connection part connected to the 3-1st light-emitting device;
a 2-2nd connection line including a 2-2nd emission connection part connected to the fourth light-emitting device; and
a 3-2nd connection line including a 3-2nd emission connection part connected to the 3-2nd light-emitting device,
wherein the 3-2nd, 2-2nd, and 3-1st emission connection parts are spaced apart from the 1-1st, 2-1st, and 1-2nd emission connection parts in the first direction, respectively, and the 3-1st emission connection part is spaced apart from the 3-2nd emission connection part in the second direction with the 2-2nd emission connection part disposed therebetween.

22. The display device of claim 21, wherein the 1-1st and 1-2nd light-emitting devices respectively include 1-1st and 1-2nd emission parts that provide first-color light, the second and fourth light-emitting devices respectively include 2-1st and 2-2nd emission parts that provide second-color light having a different color from the first-color light, and the 3-1st and 3-2nd light-emitting devices respectively include 3-1st and 3-2nd emission parts that provide third-color light having a different color from the first-color light and the second-color light,
wherein the 1-1st emission part and the 1-2nd emission part are spaced apart in the second direction with the 2-1st emission part disposed therebetween, the 3-1st emission part and the 3-2nd emission part are spaced apart in the second direction with the 2-2nd emission part disposed therebetween, and the 1-1st, 2-1st, and 1-2nd emission parts are spaced apart from the 3-2, 2-2nd, and 3-1st emission parts respectively in the first direction, and
wherein the 1-1st and 3-2nd emission connection parts are spaced apart from the 1-1st and 3-2 emission parts respectively in the second direction, and the 1-2nd and 3-1st emission connection parts are spaced apart from the 1-2nd and 3-1st emission parts respectively in an opposite direction to the second direction.

23. The display device of claim 21, wherein a portion of the first mesh line intersects a portion between the 1-1st emission connection part and the 2-1st emission connection part and a portion between the 3-2nd emission connection part and the 2-2nd emission connection part, and
wherein a portion of the second mesh line intersects a portion between the 1-2nd emission connection part and the 2-1st emission connection part or a portion between the 3-1st emission connection part and the 2-2nd emission connection part.

24. The display device of claim 2, wherein, in a plan view, the first mesh line and the second mesh line each extend in one direction between the second electrode of the first light-emitting device and the second electrode of the second light-emitting device, and the first mesh line and the second mesh line face each other in the one direction.

25. The display device of claim 2, wherein, in a plan view, the first mesh line and the second mesh line are spaced apart and face each other with the second electrode of the first light-emitting device disposed therebetween.

26. The display device of claim 2, wherein, in a plan view, the first mesh line and the second mesh line each extend in one direction between the second electrode of the first light-emitting device and the second electrode of the second light-emitting device, and the first mesh line and the second mesh line face each other in a direction intersecting the one direction.

27. The display device of claim 26, wherein the separator includes a first separator overlapping the first mesh line and a second separator overlapping the second mesh line and spaced apart from the first separator.

28. The display device of claim 27, wherein the first separator and the second separator are disposed between adjacent light-emitting devices.

29. The display device of claim 1, further comprising a dummy conductive pattern arranged on the separator, including the same material as the second electrode, and electrically connected to a power supply line, wherein at least a portion of an outer surface of the separator has a smaller internal angle than an inner surface of the separator.

30. The display device of claim 29, wherein the at least a portion of the outer surface of the separator has the internal angle of 95 degrees or less.

31. The display device of claim 1, further comprising an encapsulation layer covering the first light-emitting device, the second light-emitting device, and the separator, wherein the sensing electrode is arranged on the encapsulation layer.

32. A display device comprising:
transistors;
light-emitting devices arranged on the transistors;
connection lines connecting the transistors and the light-emitting devices respectively;
a first sensing electrode extending in a first direction; and
a second sensing electrode extending in a second direction and insulatively intersecting the first sensing electrode,
wherein the connection lines each include:
a driver connection part connected to a corresponding transistor among the transistors; and
an emission connection part spaced apart from the driver connection part in a plan view and connected to a corresponding light-emitting device among the light-emitting devices,
wherein the first sensing electrode and the second sensing electrode are spaced apart from each other between adjacent emission connection parts among the emission connection parts of the connection lines.
